(19) United States
(12) Patent Application Publication
(10) Pub. No.: US 2023/0317894 A1
(43) Pub. Date: Oct. 5, 2023

(54) DISPLAY DEVICE, ELECTRONIC DEVICE, AND HEAD-MOUNTED DISPLAY

(71) Applicant: SEMICONDUCTOR ENERGY LABORATORY CO., LTD., Atsugi-shi, Kanagawa-ken (JP)

(72) Inventors: Daiki NAKAMURA, Atsugi, Kanagawa (JP); Tomoya AOYAMA, Atsugi, Kanagawa (JP); Fumiyasu SEINO, Isehara, Kanagawa (JP); Tetsuji ISHITANI, Atsugi, Kanagawa (JP)

(21) Appl. No.: 18/041,839

(22) PCT Filed: Aug. 6, 2021
(86) PCT No.: PCT/IB2021/057241

§ 371 Date: Feb. 16, 2023

(30) Foreign Application Priority Data
Aug. 21, 2020 (JP) 2020-140132
Oct. 1, 2020 (JP) 2020-167184

(51) Int. Cl. H01L 33/58; G02B 27/01; H01L 33/50; H01L 33/14

(52) U.S. Cl. CPC H01L 33/58; G02B 27/0172; H01L 33/505; H01L 33/145; G02B 2027/0112; H01L 33/62

(57) ABSTRACT

A display device that enables a user to see a bright image is provided. In the display device, a first substrate, a light-emitting element, an insulating layer, a coloring layer, a planarization layer, a plano-convex lens, a resin layer, and a second substrate are stacked in this order from the bottom. The plano-convex lens is curved outwards in the upper direction of the display device. A convex portion of the plano-convex lens is in contact with a resin layer, and the refractive index of the resin layer is lower than the refractive index of the plano-convex lens. Light emitted by the light-emitting element is converged in the forward direction by the plano-convex lens.

### TECHNICAL FIELD

One embodiment of the present invention relates to a display device. One embodiment of the present invention relates to an electronic device. One embodiment of the present invention relates to a head-mounted display.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device generally means a device that can function by utilizing semiconductor characteristics.

### BACKGROUND ART

As display devices for augmented reality (AR) or virtual reality (VR), wearable display devices and stationary display devices are becoming widespread. Examples of wearable display devices include a head-mounted display (HMD) and an eyeglass-type display device. Examples of stationary display devices include a head-up display (HUD). For example, Patent Document 1 discloses a head-mounted display that is capable of capturing an image of a user's eye easily.

### REFERENCE

### Patent Document

[Patent Document 1] Japanese Published Patent Application No. 2019-80354

### SUMMARY OF THE INVENTION

### Problems to be Solved by the Invention

With a display device whose display surface is close to the user, such as an HMD, the user is likely to perceive pixels and strongly feels granularity, whereby the sense of immersion and realistic feeling of AR or VR might be diminished. Thus, a display device including minute pixels is required so that the pixels are not perceived by the user. That is, a high-resolution display device is required.

Miniaturization of pixels decreases the aperture ratio of a pixel in some cases. This might reduce the proportion of the occupied area of a display element in the occupied area of a pixel. Thus, for example, when a light-emitting element is used as the display element, the image seen by the user of the display device becomes dark in some cases. Meanwhile, when a bright image is to be displayed by the display device, a large amount of current needs to flow through the light-emitting element, which increases the power consumption of the display device and shortens the lifetime of the display device to reduce the reliability of the display device in some cases.

An object of one embodiment of the present invention is to provide a display device that enables a user to see a bright image. Another object of one embodiment of the present invention is to provide a display device with low power consumption. Another object of one embodiment of the present invention is to provide a highly reliable display device. Another object of one embodiment of the present invention is to provide a display device including minute pixels. Another object of one embodiment of the present invention is to provide a display device capable of displaying a high-quality image. Another object of one embodiment of the present invention is to provide an inexpensive display device. Another object of one embodiment of the present invention is to provide a novel display device. Another object of one embodiment of the present invention is to provide a manufacturing method of the above display device.

The description of these objects does not preclude the existence of other objects. One embodiment of the present invention does not have to achieve all the objects. Note that other objects can be derived from the description of the specification, the drawings, the claims, and the like.

### Means for Solving the Problems

One embodiment of the present invention is a display device including a first light-emitting element, a first coloring layer, a first lens, a first substrate, a second substrate, an insulating layer, a planarization layer, and a resin layer. The first lens includes a first flat portion and a first convex portion. The first light-emitting element is provided over the first substrate. The insulating layer is provided over the first light-emitting element. The first coloring layer is provided over the insulating layer to include a region overlapping with the first light-emitting element. The planarization layer is provided over the first coloring layer. The first lens is provided such that the first flat portion is in contact with the planarization layer and the first lens includes a region overlapping with the first light-emitting element. The resin layer is in contact with the first convex portion. The second substrate is in contact with the resin layer. The refractive index of the resin layer is lower than the refractive index of the first lens.

In the above embodiment, a second light-emitting element, a second coloring layer, and a second lens are included. The second lens includes a second flat portion and a second convex portion. The second light-emitting element is provided over the first substrate. The insulating layer is provided over the second light-emitting element. The second coloring layer is provided over the insulating layer to include a region overlapping with the second light-emitting element. The second lens is provided such that the second flat portion is in contact with the planarization layer and the second lens includes a region overlapping with the second light-emitting element. The resin layer is in contact with the second convex portion. The refractive index of the resin layer is lower than the refractive index of the second lens. The first coloring layer and the second coloring layer transmit light of colors that are different from each other. The thickness of the first coloring layer may be different from the thickness of the second coloring layer.

Another embodiment of the present invention is a display device including a light-emitting element, a wavelength-conversion layer, a lens, a first substrate, a second substrate, an insulating layer, a planarization layer, and a resin layer. The lens includes a flat portion and a convex portion. The light-emitting element is provided over the first substrate. The insulating layer is provided over the light-emitting element. The wavelength-conversion layer is provided over the insulating layer to include a region overlapping with the light-emitting element. The planarization layer is provided over the wavelength-conversion layer. The lens is provided such that the flat portion is in contact with the planarization layer and the lens includes a region overlapping with the light-emitting element. The resin layer is in contact with the convex portion. The second substrate is in contact with the resin layer. The refractive index of the resin layer is lower than the refractive index of the lens.

Another embodiment of the present invention is a display device including a first substrate, a first light-emitting element, a second light-emitting element, an insulating layer, a first coloring layer, a second coloring layer, a partition, a first lens, and a second lens. The first light-emitting element and the second light-emitting element are provided over the first substrate. The insulating layer is provided over the first light-emitting element and over the second light-emitting element. The partition is provided over the insulating layer. The first coloring layer is provided over the insulating layer to be in contact with a side surface of the partition and to include a region overlapping with the first light-emitting element. The second coloring layer is provided over the insulating layer to be in contact with a side surface of the partition and to include a region overlapping with second light-emitting element. The first lens is provided over the first coloring layer to include a region overlapping with the first light-emitting element. The second lens is provided over the second coloring layer to include a region overlapping with the second light-emitting element. The refractive index of the partition is lower than the refractive index of the first coloring layer and the refractive index of the second coloring layer.

In the above embodiment, the display device includes a planarization layer. The first lens includes a first flat portion and a first convex portion. The second lens includes a second flat portion and a second convex portion. The planarization layer is provided over the first coloring layer and over the second coloring layer. The first flat portion and the second flat portion may be in contact with the planarization layer.

In the above embodiment, the thickness of the first coloring layer may be different from the thickness of the second coloring layer.

Another embodiment of the present invention is a display device including a first substrate, a first light-emitting element, a second light-emitting element, an insulating layer, a wavelength-conversion layer, a partition, a first lens, and a second lens. The first light-emitting element and the second light-emitting element are provided over the first substrate. The insulating layer is provided over the first light-emitting element and over the second light-emitting element. The partition is provided over the insulating layer. The wavelength-conversion layer is provided over the insulating layer to be in contact with a side surface of the partition and to include a region overlapping with the first light-emitting element. The first lens is provided over the wavelength-conversion layer to include a region overlapping with the first light-emitting element. The second lens is provided to include a region overlapping with the second light-emitting element. The refractive index of the partition is lower than the refractive index of the wavelength-conversion layer.

In the above embodiment, the display device includes a planarization layer. The first lens includes a first flat portion and a first convex portion. The second lens includes a second flat portion and a second convex portion. The planarization layer is provided over the wavelength-conversion layer. The first flat portion and the second flat portion may be in contact with the planarization layer.

In the above embodiment, the display device includes a second substrate and a resin layer. The resin layer is in contact with the first convex portion and the second convex portion. The second substrate is in contact with the resin layer. The refractive index of the resin layer may be lower than the refractive index of the first lens and the refractive index of the second lens.

In the above embodiment, the planarization layer is in contact with an upper surface and a side surface of the first coloring layer and with an upper surface and a side surface of the second coloring layer. The refractive index of the planarization layer may be lower than the refractive index of the first coloring layer and the refractive index of the second coloring layer.

In the above embodiment, the first lens is adjacent to the second lens. The first coloring layer may be apart from the second coloring layer.

In the above embodiment, the insulating layer may be a planarized layer.

An electronic device including the display device of one embodiment of the present invention and a battery is also one embodiment of the present invention.

A head-mounted display including the display device of one embodiment of the present invention and a wearing portion is also one embodiment of the present invention.

### Effect of the Invention

One embodiment of the present invention can provide a display device that enables a user to see a bright image. Another embodiment of the present invention can provide a display device with low power consumption. Another embodiment of the present invention can provide a highly reliable display device. Another embodiment of the present invention can provide a display device including minute pixels. Another embodiment of the present invention can provide a display device capable of displaying a high-quality image. Another embodiment of the present invention can provide an inexpensive display device. Another embodiment of the present invention can provide a novel display device. Another embodiment of the present invention can provide a manufacturing method of the above display device.

The description of these effects does not preclude the existence of other effects. Note that one embodiment of the present invention does not need to have all the effects. Other effects can be derived from the description of the specification, the drawings, the claims, and the like.

### BRIEF DESCRIPTION OF THE DRAWINGS

FIG. 1A is a cross-sectional view of a structure example of a display device. FIG. 1B shows an example of the direction of light travel.

FIG. 2A and FIG. 2B are cross-sectional views each showing a structure example of a display device.

FIG. 3 is a cross-sectional view of a structure example of a display device.

FIG. 4A is a cross-sectional view of a structure example of a display device. FIG. 4B shows an example of the direction of light travel.

FIG. 5A is a cross-sectional view of a structure example of a display device. FIG. 5B shows an example of the direction of light travel.

FIG. 6A and FIG. 6B are cross-sectional views each showing a structure example of a display device.

FIG. 7A and FIG. 7B are cross-sectional views showing an example of a method for manufacturing a display device.

FIG. 8A and FIG. 8B are cross-sectional views showing an example of a method for manufacturing a display device.

FIG. 9 is a cross-sectional view of a structure example of a display device.

FIG. 10A is a top view showing an example of a transistor. FIG. 10B to FIG. 10D are cross-sectional views showing an example of a transistor.

FIG. 11A is a diagram showing the classification of crystal structures of IGZO. FIG. 11B is a diagram showing an XRD spectrum of a CAAC-IGZO film. FIG. 11C is an image showing a nanobeam electron diffraction pattern of a CAAC-IGZO film.

FIG. 12A to FIG. 12D are diagrams showing an example of an electronic device.

FIG. 13A to FIG. 13F are diagrams showing examples of electronic devices.

FIG. 14 is a schematic diagram of a display device used for simulation.

FIG. 15 is a graph showing light distribution characteristics of a light-emitting element used for simulation.

FIG. 16 is a graph showing simulation results.

FIG. 17A and FIG. 17B are electron microscope images of a display device.

FIG. 18 is a schematic diagram of a display device used for simulation.

FIG. 19 is a graph showing actual measurement results and simulation results of radiance of a display device according to Example.

### MODE FOR CARRYING OUT THE INVENTION

Hereinafter, embodiments are described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the description of the embodiments below.

Note that in structures of the present invention described below, the same portions or portions having similar functions are denoted by the same reference numerals in different drawings, and the description thereof is not repeated. The same hatching pattern is used for portions having similar functions, and the portions are not denoted by specific reference numerals in some cases.

In each drawing described in this specification, the size, the layer thickness, or the region of each component is exaggerated for clarity in some cases. Therefore, they are not limited to the illustrated scale.

Note that in this specification and the like, the ordinal numbers such as “first” and “second” are used in order to avoid confusion among components and do not limit the number.

Note that the expressions indicating directions, such as “over” and “under,” are basically used to correspond to the directions in the drawings. However, in some cases, the term “over” or “under” in the specification indicates a direction that does not correspond to the apparent direction in the drawings, for the purpose of easy description or the like. For example, when the stacked order (or formation order) of a stack is described, even in the case where a surface on which the stack is provided (e.g., a formation surface, a support surface, a bonding surface, or a flat surface) is positioned above the stack in the drawings, the direction and the opposite direction are referred to as “under” and “over”, respectively, in some cases.

Note that in this specification, an EL layer means a layer containing at least a light-emitting substance (also referred to as a light-emitting layer) or a stack including the light-emitting layer provided between a pair of electrodes of a light-emitting element.

### Embodiment 1

In this embodiment, structure examples and the like of a display device of one embodiment of the present invention are described.

### Structure Example 1

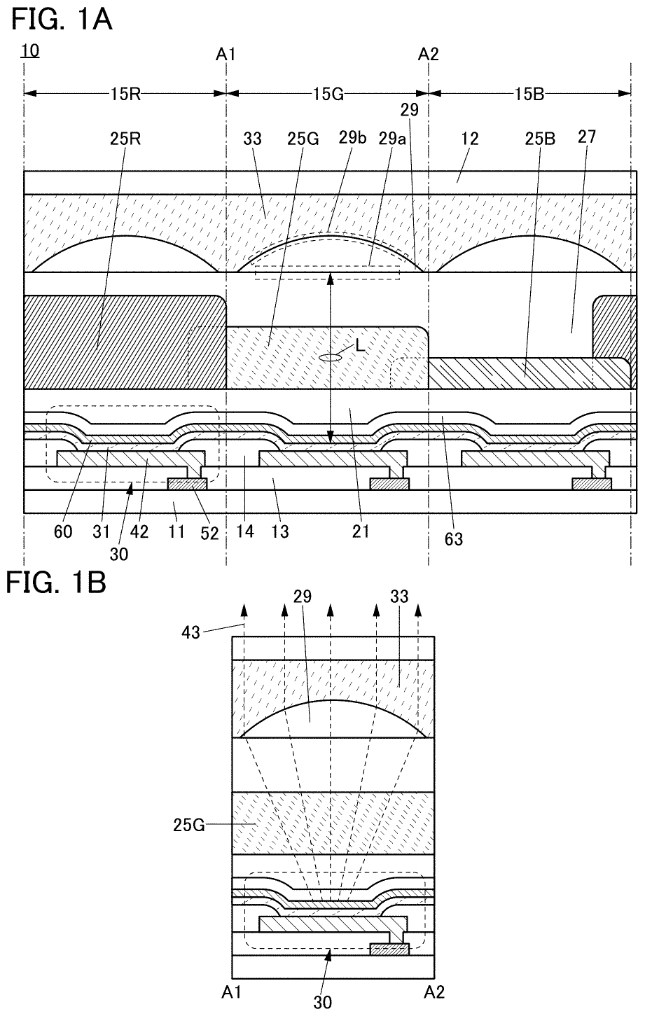

FIG. 1A is a cross-sectional view showing a structure example of a display device 10, which is a display device of one embodiment of the present invention. The display device 10 includes a pixel 15R, a pixel 15G, and a pixel 15B. Here, the pixel 15R, the pixel 15G, and the pixel 15B are provided on a display surface of the display device 10. The display surface can have a structure in which the pixels 15R, the pixels 15G, and the pixels 15B are arranged in a matrix. It can be said that one pixel is composed of the pixel 15R, the pixel 15G, and the pixel 15B, and the pixels are arranged in a matrix on the display surface of the display device 10. In this case, the pixel 15R, the pixel 15G, and the pixel 15B can be referred to as sub-pixels.

The display device 10 includes a substrate 11, a transistor 52, an insulating layer 13, a light-emitting element 30, a partition 14, an insulating layer 63, an insulating layer 21, a coloring layer 25R, a coloring layer 25G, a coloring layer 25B, a planarization layer 27, a lens 29, a resin layer 33, and a substrate 12. The pixel 15R, the pixel 15G, and the pixel 15B each include one light-emitting element 30 and one lens 29. The coloring layer 25R is provided in the pixel 15R, the coloring layer 25G is provided in the pixel 15G, and the coloring layer 25B is provided in the pixel 15B.

In this specification and the like, a light-emitting element can be referred to as a light-emitting device. In addition, a display element can be referred to as a display device.

In the display device 10 illustrated in FIG. 1A, the pixel 15G is adjacent to the pixel 15R and the pixel 15B. Here, the light-emitting elements 30, the coloring layers, and the lenses 29 provided in adjacent pixels can be said to be adjacent to each other. For example, in FIG. 1A, the light-emitting element 30 provided in the pixel 15R and the light-emitting element 30 provided in the pixel 15G can be said to be adjacent to each other. In addition, the coloring layer 25R and the coloring layer 25G that are illustrated in FIG. 1A can be said to be adjacent to each other. Furthermore, in FIG. 1A, the lens 29 provided in the pixel 15R and the lens 29 provided in the pixel 15G can be said to be adjacent to each other. Although the pixel 15R and the pixel 15B are not adjacent to each other in FIG. 1A, the pixel 15R and the pixel 15B may be adjacent to each other.

The insulating layer 13 and the transistor 52 are provided over the substrate 11. The light-emitting element 30 is provided over the insulating layer 13. The insulating layer 63 is provided over the light-emitting element 30. The insulating layer 21 is provided over the insulating layer 63. The coloring layer 25R, the coloring layer 25G, and the coloring layer 25B are provided over the insulating layer 21. The planarization layer 27 is provided over the coloring layer 25R, over the coloring layer 25G, and over the coloring layer 25B. The lens 29 is provided over the planarization layer 27. The resin layer 33 is provided over the lens 29. The substrate 12 is provided over the resin layer 33. Here, although an upper surface of the insulating layer 13 is planarized in FIG. 1A, the upper surface is not necessarily planarized.

In the case where the expression “B over A” is used in this specification and the like, for example, as long as at least part of A overlaps with at least part of B, a region where A and B are in contact with each other is not necessarily included.

As the substrate 11, an insulating substrate such as a glass substrate, a quartz substrate, a sapphire substrate, or a ceramic substrate, a single crystal semiconductor substrate or a polycrystalline semiconductor substrate including silicon, silicon carbide, or the like as a material, a compound semiconductor substrate of silicon germanium or the like, or a semiconductor substrate such as an SOI substrate can be used. Substrates having flexibility are used as the substrate 11 and the substrate 12, whereby the display device 10 can be a flexible display device.

As the insulating layer 13 and the insulating layer 21, for example, an organic insulating film is preferably used. Examples of the organic insulating film include an acrylic resin, a polyimide resin, an epoxy resin, a polyamide resin, a polyimide-amide resin, a siloxane resin, a benzocyclobutene-based resin, a phenol resin, and precursors of these resins. An inorganic insulating film, for example, is preferably used as the insulating layer 63. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, a hafnium oxynitride film, a hafnium nitride oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used. Note that an inorganic insulating film may be used as the insulating layer 13 or the insulating layer 21, and an organic insulating film may be used as the insulating layer 63. As any other insulating layer included in the display device 10, a material similar to the material that can be used as the insulating layer 13, the insulating layer 63, or the insulating layer 21 can be used.

In this specification and the like, the term silicon oxynitride refers to a material that contains more oxygen than nitrogen in its composition. Moreover, in this specification and the like, the term silicon nitride refers to a material that contains more nitrogen than oxygen in its composition.

As illustrated in FIG. 1A, the coloring layer 25R, the coloring layer 25G, and the coloring layer 25B are provided over their respective light-emitting elements 30. In addition, the lenses 29 that are different from one another are provided over the coloring layer 25R, over the coloring layer 25G, and over the coloring layer 25B. Thus, the light-emitting element 30, the coloring layer 25R, and the lens 29 are provided to include a region where they overlap with one another. The light-emitting element 30, the coloring layer 25G, and the lens 29 are provided to include a region where they overlap with one another. The light-emitting element 30, the coloring layer 25B, and the lens 29 are provided to include a region where they overlap with one another.

In FIG. 1A, a dotted line indicates a structure including a region where two kinds of coloring layers overlap with each other. Moreover, in FIG. 1A, the lenses 29 are provided apart from one another. Note that the coloring layers do not necessarily overlap with each other and the lenses 29 provided in adjacent pixels may include a region where they are in contact with each other.

The light-emitting element 30 has a structure in which a conductive layer 42, a light-emitting layer 31, and a conductive layer 60 are stacked. Here, the conductive layer 42 can be a pixel electrode of the light-emitting element 30 and the conductive layer 60 can be a common electrode of the light-emitting element 30.

The light-emitting element 30 can emit white light, for example. Specifically, white light can be emitted by the light-emitting layer 31. As the light-emitting element 30, an EL element such as an OLED (Organic Light Emitting Diode) or a QLED (Quantum-dot Light Emitting Diode) can be used. As the light-emitting element 30, a micro LED can be used.

In the case where a light-emitting element emitting white light is used as the light-emitting element 30, the light-emitting layer 31 preferably contains two or more kinds of light-emitting substances. A white emission can be obtained by selecting light-emitting substances so that two or more light-emitting substances emit light of complementary colors, for example. For example, it is preferable to contain two or more out of light-emitting substances emitting light of R (red), G (green), B (blue), Y (yellow), O (orange), and the like or light-emitting substances emitting light containing two or more of spectral components of R, G, and B. A light-emitting element whose emission spectrum has two or more peaks in the wavelength range of a visible light region (e.g., 350 nm to 750 nm) is preferably employed. An emission spectrum of a material emitting light having a peak in a yellow wavelength range preferably includes spectral components also in green and red wavelength ranges.

The light-emitting layer 31 preferably has a structure in which a light-emitting layer containing a light-emitting material emitting light of one color and a light-emitting layer containing a light-emitting material emitting light of another color are stacked. For example, the plurality of light-emitting layers in the light-emitting layer 31 may be stacked in contact with each other or may be stacked with a region not including any light-emitting material therebetween. For example, between a fluorescent layer and a phosphorescent layer, a region that contains the same material as the fluorescent layer or phosphorescent layer (for example, a host material or an assist material) and no light-emitting material may be provided. This facilitates the fabrication of the light-emitting element 30 and reduces the drive voltage. When the light-emitting element 30 has a structure in which a plurality of light-emitting layers 31 are stacked, the plurality of light-emitting layers 31 may be stacked with a charge generation layer positioned therebetween.

The conductive layer 42 can be electrically connected to the transistor 52 through an opening that is provided in the insulating layer 13 and reaches the transistor 52. For example, the conductive layer 42 can be electrically connected to a source or a drain of the transistor 52.

The partitions 14 have a function of electrically insulating (also referred to as electrically isolating) the conductive layers 42 included in the different light-emitting elements 30. An end portion of the conductive layer 42 is covered with the partition 14.

An inorganic insulating film is preferably used as the partition 14. For example, a material similar to the material that can be used for the insulating layer 63 or the like can be used for the partition 14. Note that an organic insulating film may be used for the partition 14. The partition 14 is a layer that transmits visible light. A partition that blocks visible light may be provided instead of the partition 14.

The insulating layer 63 can be provided to cover the light-emitting element 30. The insulating layer 63 is preferably formed of a film that is unlikely to transmit impurities such as water or hydrogen. When the insulating layer 63 formed of a film that is unlikely to transmit impurities such as water or hydrogen is provided to cover the light-emitting element 30, entry of impurities such as water or hydrogen into the light-emitting element 30 can be inhibited. As a result, the reliability of the light-emitting element 30 can be increased. Thus, the insulating layer 63 functions as a protective layer for the light-emitting element 30. Note that the insulating layer 63 may be omitted, in which case the insulating layer 21 preferably has the function of the protective layer.

As described above, the insulating layer 21 can be provided over the light-emitting element 30, and the coloring layer 25R, the coloring layer 25G, and the coloring layer 25B can be provided over the insulating layer 21. For example, the coloring layer 25R, the coloring layer 25G, and the coloring layer 25B can be provided to be in contact with an upper surface of the insulating layer 21. Here, in the case where the upper surface of the insulating layer 21 is planarized as illustrated in FIG. 1A, the coloring layer 25R, the coloring layer 25G, and the coloring layer 25B can be provided on a planar surface.

The coloring layer 25R has a function of transmitting red light, for example. The coloring layer 25G has a function of transmitting green light, for example. The coloring layer 25B has a function of transmitting blue light, for example. In this case, red light is emitted from the pixel 15R, green light is emitted from the pixel 15G, and blue light is emitted from the pixel 15B. Note that the coloring layer 25R, the coloring layer 25G, or the coloring layer 25B may have a function of transmitting light of cyan, magenta, yellow, or the like. In addition, although three kinds of coloring layers are illustrated in FIG. 1A, the display device 10 may include four or more kinds of coloring layers.

For the coloring layer 25R, the coloring layer 25G, and the coloring layer 25B, a metal material, a resin material, a resin material containing pigment or dye, or the like can be used.

When the coloring layers are provided to include a region overlapping with the light-emitting element 30, separate coloring is not needed to form the light-emitting layer 31. Accordingly, the pixel in which the light-emitting element 30 is provided can be miniaturized.

Here, the coloring layers provided in adjacent pixels can partly overlap with each other. In the example shown in FIG. 1A, the coloring layer 25R and the coloring layer 25G can include a region where they overlap with each other. Furthermore, the coloring layer 25G and the coloring layer 25B can include a region where they overlap with each other. Thus, in the case where photolithography and etching are used to form the coloring layer 25R, the coloring layer 25G, and the coloring layer 25B, for example, the coloring layer 25R, the coloring layer 25G, and the coloring layer 25B can be formed even if the alignment accuracy of a mask used for the photolithography is low. Accordingly, the pixel in which the light-emitting element 30 is provided can be miniaturized.

Here, the thickness of the coloring layer 25R, the thickness of the coloring layer 25G, and the thickness of the coloring layer 25B can be different from one another. Accordingly, the color purity of light transmitted through the coloring layer and the light absorptance of the coloring layer can be balanced as desired for each color, for example. Thus, the display device 10 can display a high-quality image. Note that the thickness of the coloring layer 25R, the thickness of the coloring layer 25G, and the thickness of the coloring layer 25B may be equal to one another.

As described above, the planarization layer 27 is provided over the coloring layer 25R, over the coloring layer 25G, and over the coloring layer 25B. For example, the planarization layer 27 can be provided to be in contact with the coloring layer 25R, the coloring layer 25G, and the coloring layer 25B. Specifically, the planarization layer 27 can be provided to be in contact with upper surfaces and side surfaces of the coloring layer 25R, the coloring layer 25G, and the coloring layer 25B.

For the planarization layer 27, a material similar to the material that can be used for the insulating layer 21 can be used, for example.

As described above, the lens 29 is provided over the planarization layer 27. Here, the lens 29 can be a plano-convex lens including a flat portion 29a and a convex portion 29b. The lens 29 can be provided such that the flat portion 29a faces toward the substrate 11 and the convex portion 29b faces toward the substrate 12. For example, the lens 29 can be provided such that the flat portion 29a is in contact with an upper surface of the planarization layer 27.

As described above, the thickness of the coloring layer 25R, the thickness of the coloring layer 25G, and the thickness of the coloring layer 25B can be different from one another. Even in such a case, the planarization layer 27 is provided over the coloring layer 25R, over the coloring layer 25G, and over the coloring layer 25B and the lenses 29 are provided over the planarization layer 27, whereby the flat portions 29a of the lenses 29 can be provided on the same plane. Consequently, distances L from the light-emitting layers 31 of the light-emitting elements 30 to the flat portions 29a of the lenses 29 can be equal to one another. Specifically, the distance from the light-emitting layer 31 overlapping with the coloring layer 25R to the flat portion 29a, the distance from the light-emitting layer 31 overlapping with the coloring layer 25G to the flat portion 29a, and the distance from the light-emitting layer 31 overlapping with the coloring layer 25B to the flat portion 29a can be equal to one another.

The resin layer 33 is provided to be in contact with the convex portion 29b of the lens 29. The substrate 12 is provided to be in contact with an upper surface of the resin layer 33. The lens 29 and the substrate 12 can be bonded to each other with the resin layer 33.

As the resin layer 33, an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used. Alternatively, a two-component-mixture-type resin may be used. Although the details are described later, the refractive index of the resin layer 33 is preferably lower than the refractive index of the lens 29.

Although the lens 29 and the substrate 12 are bonded to each other with the resin layer 33 in FIG. 1A, one embodiment of the present invention is not limited thereto. For example, the lens 29 and the substrate 12 can be bonded to each other by evacuation of air from the space between them. In that case, a structure in which the resin layer 33 is not provided can be employed.

A substrate having a light-transmitting property is used as the substrate 12. As the substrate 12, a glass substrate, a quartz substrate, a sapphire substrate, or the like can be used, for example. Substrates having flexibility are used as the substrate 12 as well as the substrate 11, whereby the display device 10 can be a flexible display device.

FIG. 1B is a view of the portion between the dashed-dotted line A1 and the dashed-dotted line A2, which is extracted from the cross-sectional view of FIG. 1A. In FIG. 1B, light 43 indicates light emitted by the light-emitting element 30.

In this specification and the like, the term “light” can be replaced with the term “luminous flux” in some cases.

The light 43 is emitted not only in the forward direction but also in an oblique direction by the light-emitting element 30. On the assumption that the light 43 emitted in an oblique direction passes from the pixel while the angle is unchanged, for example, when the user of the display device 10 looks at the display surface of the display device 10 from the front, the user of the display device 10 cannot see the light 43 emitted in an oblique direction in some cases. Here, since the light emitted by the light-emitting element 30 is incident on the flat portion 29a of the lens 29, the refractive index of the resin layer 33 is lower than the refractive index of the lens 29 as described above, whereby the light emitted in an oblique direction as illustrated in FIG. 1B can be converged in the forward direction according to Snell's law. Thus, for example, when the user of the display device 10 looks at the display surface of the display device 10 from the front, the amount of light 43 seen by the user of the display device 10 can be increased. Accordingly, the user of the display device 10 can see a bright image. Furthermore, the intensity of light emitted by the light-emitting element 30 can be kept low, and accordingly the display device 10 can have low power consumption and high reliability.

The refractive index of the lens 29 can be higher than or equal to 1.5 and lower than or equal to 1.8, for example, higher than or equal to 1.5 and lower than or equal to 1.6 or can be 1.56, for example. The refractive index of the resin layer 33 can be higher than or equal to 1.2 and lower than or equal to 1.5, for example, higher than or equal to 1.3 and lower than 1.5 or can be 1.40, for example. Note that when the resin layer 33 is not provided and the lens 29 and the substrate 12 are bonded to each other by evacuation of air from the space between them, the refractive index of the lens 29 is preferably higher than 1.

The distance L is preferably determined such that the relationship represented by Formula (1) holds. Here, R1 represents the radius of curvature of the convex portion 29b, N1 represents the refractive index of the lens 29, N2 represents the refractive index of the resin layer 33, and N3 represents the refractive index of the planarization layer 27. Note that the focal length of the lens 29 is “R1×N3/(N1−N2).”

0.1×R1×N3/(N1−N2)≤L≤5×R1×N3/(N1−N2) (1)

As described above, the thickness of the coloring layer 25R, the thickness of the coloring layer 25G, and the thickness of the coloring layer 25B can be different from one another. This means that the distances L of the respective pixels are different when the lenses 29 are provided over the coloring layer 25R, over the coloring layer 25G, and over the coloring layer 25B without the planarization layer 27. If the distances L of the respective pixels are different, the radius of curvatures R2 of the convex portions 29b or the refractive indexes N1 of the lenses 29 of the respective pixels need to be changed according to Formula (1) in some cases. In that case, the lenses 29 of the respective pixels are formed separately, and accordingly the manufacturing process of the display device is complicated. Meanwhile, in the display device 10, the lenses 29 are provided over the planarization layer 27, and therefore the distances L of the respective pixels can be equal to one another. Thus, the manufacturing process of the display device 10 can be simplified. This can reduce the manufacturing cost of the display device 10 and make the display device 10 inexpensive.

### Structure Example 2

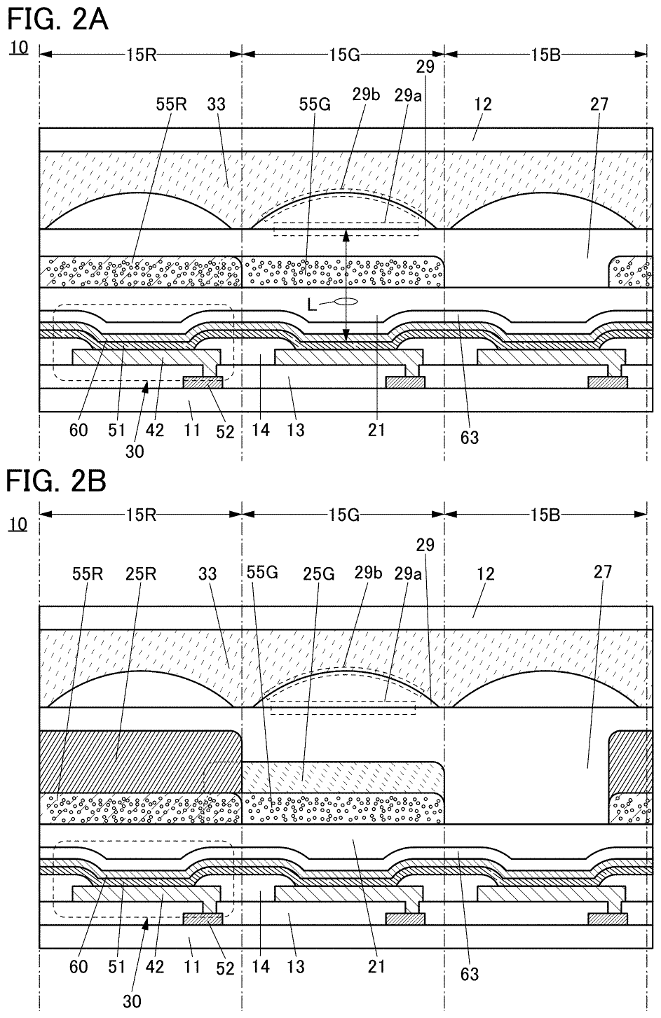

FIG. 2A shows a modification example of the display device 10 illustrated in FIG. 1A. The display device 10 illustrated in FIG. 2A is different from the display device 10 illustrated in FIG. 1A in that a light-emitting layer 51 is provided instead of the light-emitting layer 31 and a wavelength-conversion layer 55R and a wavelength-conversion layer 55G are provided instead of the coloring layer 25R, the coloring layer 25G, and the coloring layer 25B.

The light-emitting layer 51 has a function of emitting blue light, for example. The wavelength-conversion layer 55R provided in the pixel 15R has a function of converting the light emitted by the light-emitting layer 51 into red light. The wavelength-conversion layer 55G provided in the pixel 15G has a function of converting the light emitted by the light-emitting layer 51 into green light. Here, when the light-emitting layer 51 emits blue light, a wavelength-conversion layer in the pixel 15B may be omitted. Note that the light-emitting layer 51 may have a function of emitting ultraviolet light, in which case blue light can be emitted from the pixel 15B that is provided with a wavelength-conversion layer having a function of converting the light emitted by the light-emitting layer 51 into blue light.

The wavelength-conversion layer 55R and the wavelength-conversion layer 55G preferably include a fluorescent material or a quantum dot (QD). In particular, a quantum dot can give emission with high color purity since the emission spectrum thereof has a narrow peak width and the conversion efficiency is high. The display device 10 thus can have high color reproducibility, and accordingly the display device 10 can display a high-quality image.

The wavelength-conversion layer 55R and the wavelength-conversion layer 55G can have a structure in which a phosphor or quantum dots is/are dispersed in an organic resin. As the organic resin, a curable material which transmits light emitted by the light-emitting layer 51 and light emitted through the wavelength-conversion layer 55R or the wavelength-conversion layer 55G can be used.

The wavelength-conversion layer 55R and the wavelength-conversion layer 55G can be formed by, for example, a droplet discharge method (e.g., an inkjet method), a coating method, an imprinting method, a variety of printing methods (screen printing or offset printing), or the like. When a photosensitive resin material is used as the organic resin, the wavelength-conversion layer 55R and the wavelength-conversion layer 55G may be formed by application of the organic resin with a spin coat method or the like, exposure treatment, and then development treatment to shape a desired form.

There is no particular limitation on a material of a quantum dot, and examples include a Group 14 element, a Group 15 element, a Group 16 element, a compound of a plurality of Group 14 elements, a compound of an element belonging to any of Group 4 to Group 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot whose composition is represented by a given ratio may also be used.

Examples of the quantum dot include core-type quantum dots, core-shell quantum dots, and core-multishell quantum dots. Quantum dots have a high proportion of surface atoms and thus have high reactivity and easily aggregate together. For this reason, it is preferable that a protective agent be attached to, or a protective group be provided on the surfaces of quantum dots. The attachment of the protective agent or the provision of the protective group can prevent aggregation and increase solubility in a solvent. It can also reduce reactivity and improve electrical stability.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size becomes smaller; thus, the emission wavelengths of the quantum dots can be adjusted over a wavelength range of a spectrum of an ultraviolet region, a visible light region, and an infrared region by changing the size of quantum dots. The size (diameter) of the quantum dots is, for example, greater than or equal to 0.5 nm and less than or equal to 20 nm, preferably greater than or equal to 1 nm and less than or equal to 10 nm. The emission spectra are narrowed as the size distribution of the quantum dots gets smaller, and thus light can be obtained with high color purity. The shape of the quantum dots is not particularly limited to a ballistic shape and may be a spherical shape, a rod shape, a circular shape, or the like.

Here, when quantum dots are dispersed in the wavelength-conversion layer 55R and the wavelength-conversion layer 55G, the directivity of light emitted through the wavelength-conversion layer 55R and light emitted through the wavelength-conversion layer 55G are low. However, in the display device 10, the flat portion 29a of the lens 29 faces toward the wavelength-conversion layer 55R and the wavelength-conversion layer 55G and the convex portion 29b faces toward the substrate 12. In addition, in the display device 10, the refractive index of the resin layer 33 is lower than the refractive index of the lens 29. Hence, even when the directivity of the light emitted through the wavelength-conversion layer 55R and the light emitted through the wavelength-conversion layer 55G are low, the lens 29 enables the light to be converged in the forward direction. Thus, for example, when the user of the display device 10 looks at the display surface of the display device 10 from the front, the amount of the light 43 seen by the user of the display device 10 can be increased. Accordingly, the user of the display device 10 can see a bright image. Furthermore, the intensity of light emitted by the light-emitting element 30 can be kept low, and accordingly the display device 10 can have low power consumption and high reliability.

In the display device 10 illustrated in FIG. 2A, no wavelength-conversion layer is provided in the pixel 15B while the wavelength-conversion layers are provided in the pixel 15R and the pixel 15G. However, owing to the planarization layer 27 and the lenses 29 over the planarization layer 27, the flat portion 29a of the lens 29 provided in the pixel 15R or the pixel 15G and the flat portion 29a of the lens 29 provided in the pixel 15B can be provided on the same plane. Thus, the distances L from the light-emitting layer of the light-emitting elements 30 to the flat portions 29a of the lenses 29 can be equal to one another, and accordingly the manufacturing process of the display device 10 can be simplified.

### Structure Example 3

FIG. 2B shows a modification example of the display device 10 illustrated in FIG. 2A. The display device 10 illustrated in FIG. 2B is different from the display device 10 illustrated in FIG. 2A in that the coloring layer 25R and the coloring layer 25G are provided.

The coloring layer 25R is provided over the wavelength-conversion layer 55R. The coloring layer 25G is provided over the wavelength-conversion layer 55G.

The wavelength of part of light from the light-emitting layer 51, which is incident on the wavelength-conversion layer 55R or the wavelength-conversion layer 55G, is not converted in some cases. For this reason, for example, when the light-emitting layer 51 emits blue light, red light emitted through the wavelength-conversion layer 55R or green light emitted through the wavelength-conversion layer 55G might be mixed with the blue light emitted by the light-emitting layer 51 to decrease the color purity. In view of this, the coloring layer 25R is placed closer to the substrate 12 than the wavelength-conversion layer 55R is and the coloring layer 25G is placed closer to the substrate 12 than the wavelength-conversion layer 55G is, whereby the blue light transmitted through the wavelength-conversion layer 55R or the wavelength-conversion layer 55G can be inhibited from being extracted to the outside of the display device 10. The above can inhibit a reduction in the color purity of light emitted from the pixel 15R and light emitted from the pixel 15G, and accordingly the display device 10 can display a high-quality image.

### Structure Example 4

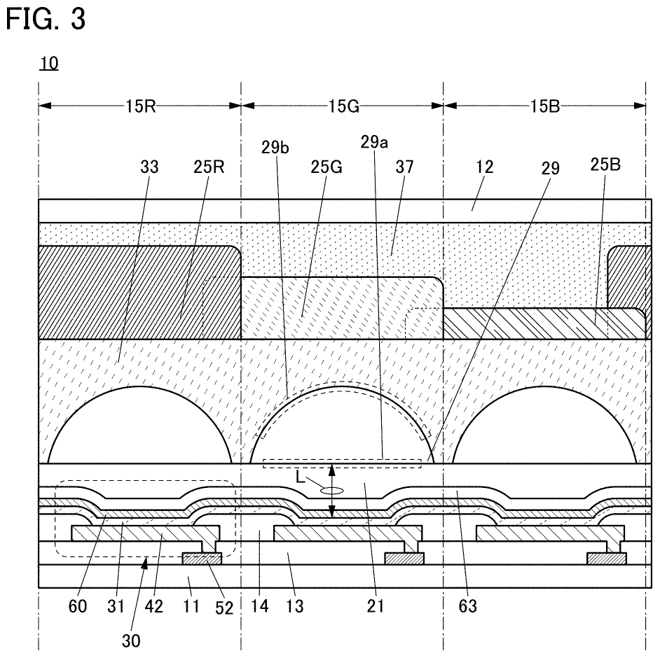

FIG. 3 is a cross-sectional view illustrating another structure example of the display device 10. The display device 10 illustrated in FIG. 3 is different from the display device 10 illustrated in FIG. 1A in the structure of the layers above the insulating layer 21.

In the display device 10 illustrated in FIG. 3, the lens 29 is provided over the insulating layer 21. For example, the flat portion 29a of the lens 29 can be provided to be in contact with the upper surface of the insulating layer 21. The resin layer 33 is provided to be in contact with the convex portion 29b of the lens 29. As described above, the refractive index of the resin layer 33 is preferably lower than the refractive index of the lens 29.

The coloring layer 25R, the coloring layer 25G, and the coloring layer 25B are provided over the resin layer 33. In addition, an adhesive layer 37 is provided over the coloring layer 25R, over the coloring layer 25G, and over the coloring layer 25B. For the adhesive layer 37, a variety of curable adhesives such as a photocurable adhesive like an ultraviolet curable adhesive, a reactive curable adhesive, a thermosetting adhesive, and an anaerobic adhesive can be used, and, for example, a material similar to the material that can be used for the resin layer 33 can be used.

Over the adhesive layer 37, the substrate 12 is provided. With the adhesive layer 37, the coloring layer 25R, the coloring layer 25G, and the coloring layer 25B can be bonded to the substrate 12.

In the display device 10 illustrated in FIG. 3, the lens 29 is provided between the light-emitting element 30 and each of the coloring layer 25R, the coloring layer 25G, and the coloring layer 25B. Thus, the distance L from the light-emitting layer 31 of the light-emitting element 30 to the flat portion 29a of the lens 29 can be made shorter than that in the display device 10 illustrated in FIG. 1A and the like. Therefore, as can be seen from Formula (1), the radius of curvature R1 of the convex portion 29b can be reduced. Consequently, the refractive index N1 of the lens 29 can be increased. In addition, the refractive index N2 of the resin layer 33 can be decreased. Furthermore, the refractive index N3 of the planarization layer 27 can be decreased.

### Structure Example 5

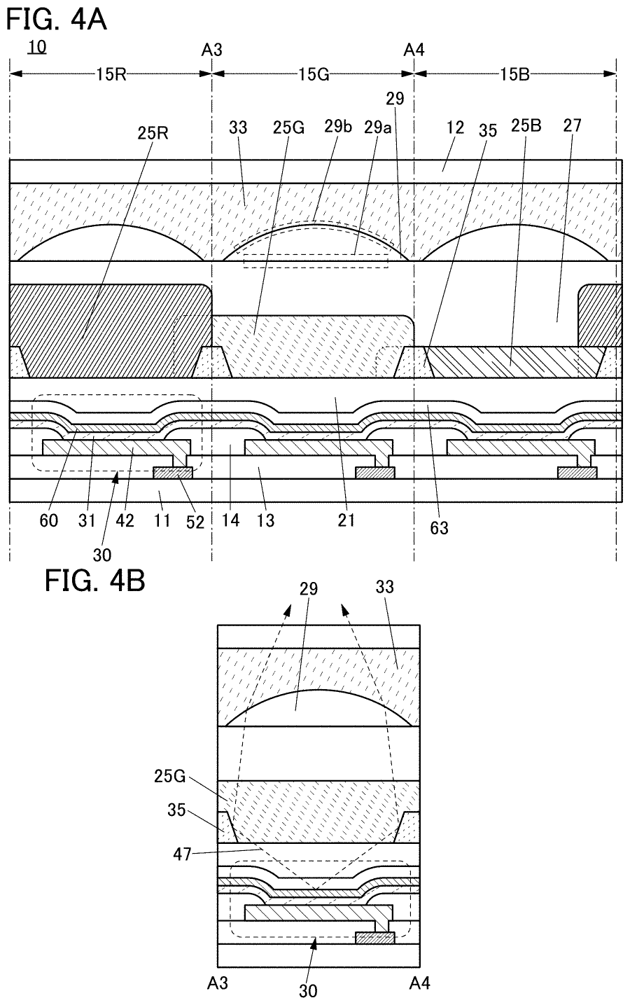

FIG. 4A is a cross-sectional view illustrating another structure example of the display device 10. The display device 10 illustrated in FIG. 4A is different from the display device 10 illustrated in FIG. 1A in including a partition 35.

The partition 35 can be provided at the boundary between pixels. For example, the partition 35 can be provided to extend over the pixel 15R and the pixel 15G as illustrated in FIG. 4A. In addition, the partition 35 can be provided to extend over the pixel 15G and the pixel 15B.

The partition 35 is provided over the insulating layer 21. For example, the partition 35 can be provided to be in contact with the upper surface of the insulating layer 21. The shape of the partition 35 can be a hexahedron, for example.

The coloring layer 25R, the coloring layer 25G, and the coloring layer 25B can each be provided to be in contact with a side surface of the partition 35. Here, at the boundary between the pixel 15R and the pixel 15G, the partition 35 can have a structure in which its side surface in contact with the coloring layer 25R is opposite the side surface in contact with the coloring layer 25G, for example. In addition, at the boundary between the pixel 15G and the pixel 15B, the partition 35 can have a structure in which its side surface in contact with the coloring layer 25G is opposite the side surface in contact with the coloring layer 25B, for example.

Here, although the details are described later, the refractive index of the partition 35 is preferably lower than the refractive indices of the coloring layer 25R, the coloring layer 25G, and the coloring layer 25B. For the partition 35 with such a structure, polymer including fluorine is preferably used, for example. For the partition 35, an organic insulating film of an acrylic resin, a polyimide resin, an epoxy resin, a polyamide resin, a polyimide-amide resin, a siloxane resin, a benzocyclobutene-based resin, a phenol resin, precursors of these resins, or the like can be used. Note that for the partition 35, an inorganic insulating film may be used.

FIG. 4B is a view of the portion between the dashed-dotted line A3 and the dashed-dotted line A4, which is extracted from the cross-sectional view of FIG. 4A. In FIG. 4B, light 47 indicates light that is emitted by the light-emitting element 30 and irradiates the partition 35.

When the refractive index of the partition 35 is lower than the refractive index of the coloring layer 25R, the refractive index of the coloring layer 25G, and the refractive index of the coloring layer 25B, the light 47 is totally reflected at the interface between the partition 35 and the coloring layer (the coloring layer 25G in FIG. 4B). Consequently, it is possible to inhibit the light 47 from being incident on and absorbed by a portion where two or more kinds of coloring layers overlap with each other. Thus, the display device 10 illustrated in FIG. 4A can have high light extraction efficiency. Accordingly, the user of the display device 10 illustrated in FIG. 4A can see a bright image. Furthermore, the display device 10 illustrated in FIG. 4A can have low power consumption and high reliability.

In the display device 10 illustrated in FIG. 4A, the light 47 incident on the coloring layer provided in an adjacent pixel, for example, can be inhibited, whereby the color purity can be increased. Consequently, the display device 10 can display a high-quality image.

Since the reflection of the light 47 by the partition 35 is total reflection, absorption of the light 47 into the partition 35 can be inhibited as compared with the case in which a reflective material such as metal is used as the partition 35, for example. Thus, the display device 10 illustrated in FIG. 4A can have high light extraction efficiency. Note that in the case where the absorption of the light 47 into the partition 35 is at an acceptable level, a reflective material such as metal may be used as the partition 35.

Here, the taper angle of the partition 35 is preferably adjusted so that the light 47 can be totally reflected and the totally reflected light 47 incident on an adjacent pixel can be inhibited. For example, if the taper angle is small, that is, the side surface of the partition 35 is nearly perpendicular, the light 47 totally reflected by the side surface of the partition 35 might be incident on an adjacent pixel. For example, the light 47 totally reflected by the partition 35 might be incident on the lens 29 provided in an adjacent pixel. By contrast, if the taper angle is large, that is, the side surface of the partition 35 is nearly horizontal, the angle at which the light 47 is incident on the interface between the partition 35 and the coloring layer is small, so that no total reflection of the light 47 might occur. In view of the above, the taper angle of the partition 35 is preferably adjusted.

Although the thickness of the partition 35 is equal to that of the coloring layer 25B in FIG. 4A, one embodiment of the present invention is not limited thereto. The thickness of the partition 35 may be smaller or larger than the thickness of the coloring layer 25B. The thickness of the partition 35 may be smaller or larger than the thickness of the coloring layer 25G. The thickness of the partition 35 may be smaller or larger than the thickness of the coloring layer 25R. Increasing the thickness of the partition 35 can reduce the light that is part of the light emitted by the light-emitting element 30 and leaks to an adjacent pixel without incidence on the partition 35. By contrast, decreasing the thickness of the partition 35 can reduce the aspect ratio of the partition 35, which can inhibit breakage of the partition 35 in the manufacturing process of the display device 10.

### Structure Example 6

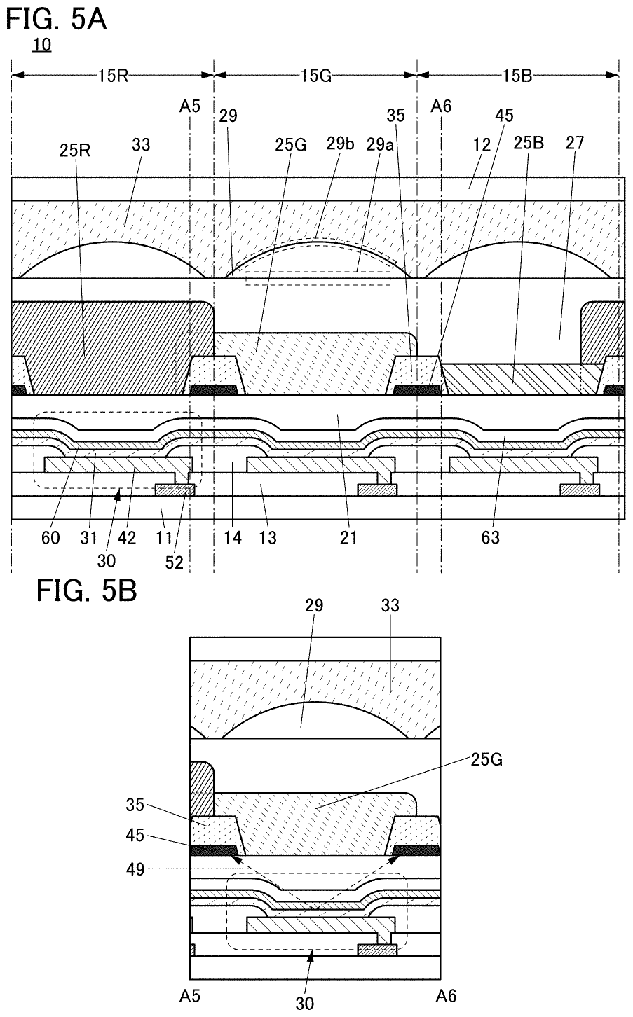

FIG. 5A shows a modification example of the display device 10 illustrated in FIG. 4A. The display device 10 illustrated in FIG. 5A is different from the display device 10 illustrated in FIG. 4A in that a light-blocking layer 45 is provided.

The light-blocking layer 45 can be provided between a layer in which the light-emitting element 30 is provided and a layer in which the partition 35 is provided. In the example in FIG. 5A, the light-blocking layer 45 is provided to be in contact with the upper surface of the insulating layer 21 and the partition 35 is provided to be in contact with an upper surface of the light-blocking layer 45.

FIG. 5B is a view of the portion between the dashed-dotted line A5 and the dashed-dotted line A6, which is extracted from the cross-sectional view of FIG. 5A. In FIG. 5B, light 49 indicates light that is emitted by the light-emitting element 30 and irradiates a bottom surface of the light-blocking layer 45.

In the display device 10 without the light-blocking layer 45, a bottom surface of the partition 35 is irradiated with the light 49. If the refractive index of the partition 35 is lower than the refractive index of the insulating layer 21, the light 49 might be totally reflected at the interface between the bottom surface of the partition 35 and the upper surface of the insulating layer 21. This might cause the light 49 to stray and leak to an adjacent pixel. By contrast, when the light-blocking layer 45 is provided, the light 49 can be absorbed by the light-blocking layer 45. This can inhibit leakage of the light 49 to an adjacent pixel. Thus, the light 49 incident on the coloring layer provided in an adjacent pixel, for example, can be inhibited, whereby the color purity can be increased. Consequently, the display device 10 can display a high-quality image.

In the structure in FIG. 5A, the partition 35 covers a side surface of the light-blocking layer 45. This structure can inhibit the side surface of the light-blocking layer 45 from absorbing the light that would be incident on the side surface of the partition 35 and totally reflected at the interface with the coloring layer if there was no light-blocking layer 45. Note that the side surface of the light-blocking layer 45 may be in contact with the coloring layer without being covered with the partition 35.

As the light-blocking layer 45, carbon black, a metal oxide, a composite oxide containing a solid solution of a plurality of metal oxides, or the like can be used.

### Structure Example 7

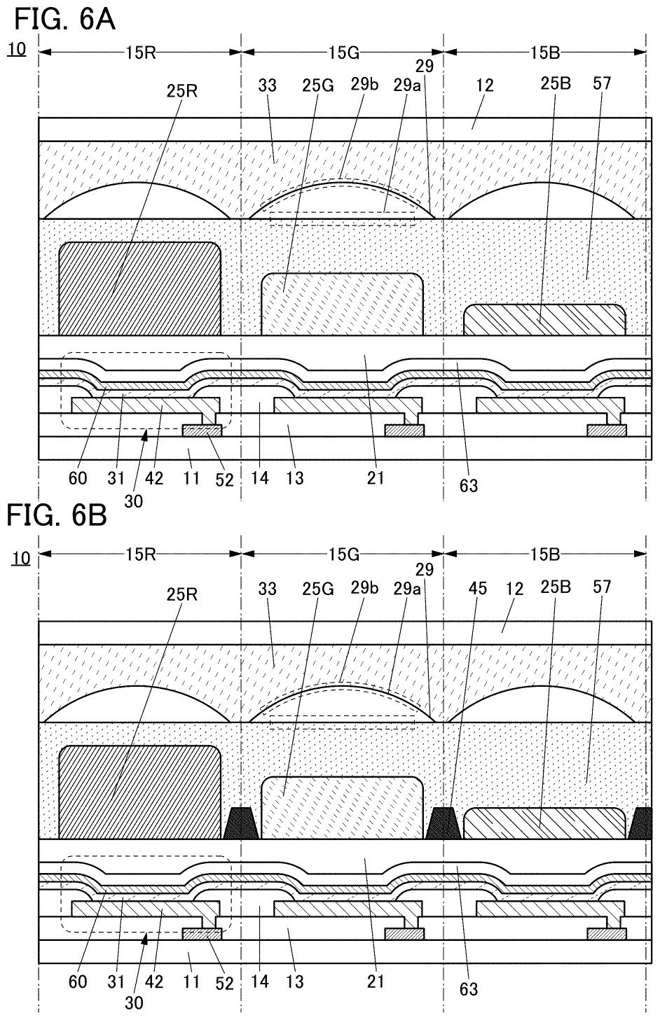

FIG. 6A is a cross-sectional view showing another structure example of the display device 10. The display device 10 illustrated in FIG. 6A is different from the display device 10 illustrated in FIG. 1A in that the coloring layer 25R, the coloring layer 25G, and the coloring layer 25B are provided apart from each other. The display device is different from the display device 10 illustrated in FIG. 1A also in that a planarization layer 57 is provided instead of the planarization layer 27.

In the display device 10 illustrated in FIG. 6A, the refractive index of the planarization layer 57 is preferably lower than the refractive indices of the coloring layer 25R, the coloring layer 25G, and the coloring layer 25B. Thus, the light emitted by the light-emitting element 30 can be totally reflected at the interface between the side surface of the coloring layer 25R, the coloring layer 25G, or the coloring layer 25B and the planarization layer 57. Accordingly, as in the case of the display device 10 illustrated in FIG. 4A, the user of the display device 10 illustrated in FIG. 6A can see a bright image. Furthermore, the display device 10 illustrated in FIG. 6A can have low power consumption and high reliability.

For the planarization layer 57, a material similar to the material that can be used for the resin layer 33 can be used. For the planarization layer 57, a material similar to the material that can be used for the partition 35 can be used.

As described above, despite the absence of the partition 35, the display device 10 illustrated in FIG. 6A can exert an effect like the structure with the partition 35. Thus, as the partition 35 is not provided, the manufacturing process of the display device 10 illustrated in FIG. 6A can be simplified. This can reduce the manufacturing cost of the display device 10 and make the display device 10 inexpensive.

### Structure Example 8

FIG. 6B shows a modification example of the display device 10 illustrated in FIG. 6A. The display device 10 illustrated in FIG. 6B is different from the display device 10 illustrated in FIG. 6A in that the light-blocking layer 45 is provided.

In the structure of the display device 10 where the coloring layers do not overlap with one another, part of the light emitted by the light-emitting element 30 leaks to an adjacent pixel and the leakage light is incident on the coloring layer provided in the adjacent pixel in some cases. For example, part of the light emitted by the light-emitting element 30 provided in the pixel 15G is incident on the coloring layer 25R or the coloring layer 25B in some cases. Here, providing the light-blocking layer 45 as illustrated in FIG. 6B can inhibit the above light leakage to increase the color purity. Thus, the display device 10 can display a high-quality image.

In the display device 10 illustrated in FIG. 6B, the light-blocking layer 45 is provided apart from the coloring layer 25R, the coloring layer 25G, and the coloring layer 25B. Thus, the proportion of light incident on the light-blocking layer 45 of the light incident on the coloring layer 25R, the coloring layer 25G, or the coloring layer 25B can be lowered as compared with the case in which the light-blocking layer 45 overlaps with part of the coloring layer 25R, the coloring layer 25G, or the coloring layer 25B. Note that the light-blocking layer 45 may overlap with part of the coloring layer 25R, the coloring layer 25G, or the coloring layer 25B.

The structures described in this specification can be implemented in combination as appropriate. For example, the structure illustrated in FIG. 2A or FIG. 2B can be implemented in combination with the structure illustrated in FIG. 3, FIG. 4A, FIG. 5A, FIG. 6A, or FIG. 6B. Specifically, for example, the wavelength-conversion layer 55R and the wavelength-conversion layer 55G can be provided in the structure illustrated in FIG. 3, FIG. 4A, FIG. 5A, FIG. 6A, or FIG. 6B.

### Example of Manufacturing Method

An example of a manufacturing method of the display device 10 will be described below with reference to drawings. Here, description is made using the display device 10 illustrated in FIG. 1A as an example.

Note that thin films that form the display device (insulating films, semiconductor films, conductive films, coloring films, and the like) can be formed by a sputtering method, a chemical vapor deposition (CVD) method, a vacuum evaporation method, a pulsed laser deposition (PLD) method, an atomic layer deposition (ALD) method, or the like. As the CVD method, a plasma-enhanced chemical vapor deposition (PECVD) method or a thermal CVD method may be used. As an example of the thermal CVD method, a metal organic chemical vapor deposition (MOCVD) method may be used.

The thin films that form the display device can be formed by a method such as spin coating, dipping, spray coating, ink-jetting, dispensing, screen printing, offset printing, a doctor knife, a slit coater, a roll coater, a curtain coater, and a knife coater.

When the thin films that form the display device are processed, a lithography method or the like can be used for the processing. Alternatively, island-shaped thin films may be formed by a deposition method using a blocking mask. Alternatively, the thin films may be processed by a nanoimprinting method, a sandblasting method, a lift-off method, or the like. The following two examples of a photolithography method can be given. In one method, a photosensitive resist material is applied onto a thin film to be processed and exposed to light through a photomask; development is performed to form a resist mask; the thin film is processed by etching or the like; then, the resist mask is removed. In the other method, after a photosensitive thin film is formed, exposure and development are performed, so that the thin film is processed into a desired shape.

In the case of using light in the lithography method, for example, an i-line (a wavelength of 365 nm), a g-line (a wavelength of 436 nm), and an h-line (a wavelength of 405 nm), or combined light of any of them can be used for light exposure. Besides, ultraviolet light, KrF laser light, ArF laser light, or the like can be used. Exposure may be performed by liquid immersion exposure technique. As the light used for the exposure, extreme ultraviolet (EUV) light or X-rays may be used. Furthermore, instead of the light used for the exposure, an electron beam can also be used. It is preferable to use extreme ultra-violet light, X-rays, or an electron beam because extremely minute processing can be performed. Note that when light exposure is performed by scanning of a beam such as an electron beam, a photomask is unnecessary.

For etching of the thin films, a dry etching method, a wet etching method, a sandblast method, or the like can be used.

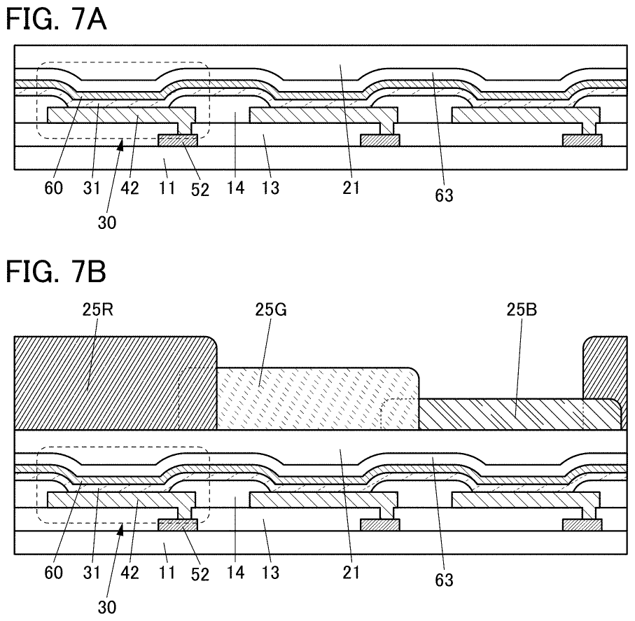

As illustrated in FIG. 7A, the transistor 52 is first formed over the substrate 11. Next, the insulating layer 13 is formed over the substrate 11 and over the transistor 52. Then, an opening reaching the transistor 52 is formed in the insulating layer 13. Next, a conductive film to be the conductive layer 42 is formed over the insulating layer 13, and the conductive film is partly etched to form the conductive layer 42.

Then, the partition 14 is formed to cover an end portion of the conductive layer 42. Next, the light-emitting layer 31 and the conductive layer 60 are formed.

The light-emitting layer 31 can be formed by an evaporation method, a coating method, a printing method, a discharge method, or the like. For the light-emitting layer 31, for example, an evaporation method not using a metal mask can be used. The conductive layer 60 can be formed by an evaporation method, a sputtering method, or the like.

Then, the insulating layer 63 is formed over the conductive layer 60. The light-emitting element 30 is sealed with the inorganic insulating layer 63. After the conductive layer 60 is formed, the insulating layer 63 is preferably formed without exposure to the air.

Next, the insulating layer 21 is formed over the insulating layer 63. For example, an organic insulating film is formed by a spin coating method or the like. Forming an organic insulating film by a spin coating method or the like enables the insulating layer 21 to be a planarization layer. Note that the upper surface of the insulating layer 21 is not necessarily planarized.

Then, the coloring layer 25R, the coloring layer 25G, and the coloring layer 25B are formed over the insulating layer 21 (FIG. 7B). Here, the coloring layers are preferably formed in the ascending order of thickness. Thus, in the example shown in FIG. 7B, preferably, after the coloring layer 25B is formed, the coloring layer 25G is formed and then the coloring layer 25R is formed.

For example, a coloring film to be the coloring layer 25B is first formed, and the coloring film is processed by a lithography method such as a photolithography method to form the coloring layer 25B. Next, a coloring film to be the coloring layer 25G is first formed, and the coloring film is processed by a lithography method such as a photolithography method to form the coloring layer 25G. Next, a coloring film to be the coloring layer 25R is first formed, and the coloring film is processed by a lithography method such as a photolithography method to form the coloring layer 25R.

In the manufacture of the display device 10 illustrated in FIG. 4A, after the insulating layer 21 is formed, a film to be the partition 35 is formed, and the film is partly etched to form the partition 35. Then, the coloring layer 25B, the coloring layer 25G, and the coloring layer 25R are formed. In the manufacture of the display device 10 illustrated in FIG. 5A, a film to be the light-blocking layer 45 is formed, and the film is partly etched to form the light-blocking layer 45; then, a film to be the partition 35 is formed, and the film is partly etched to form the partition 35.

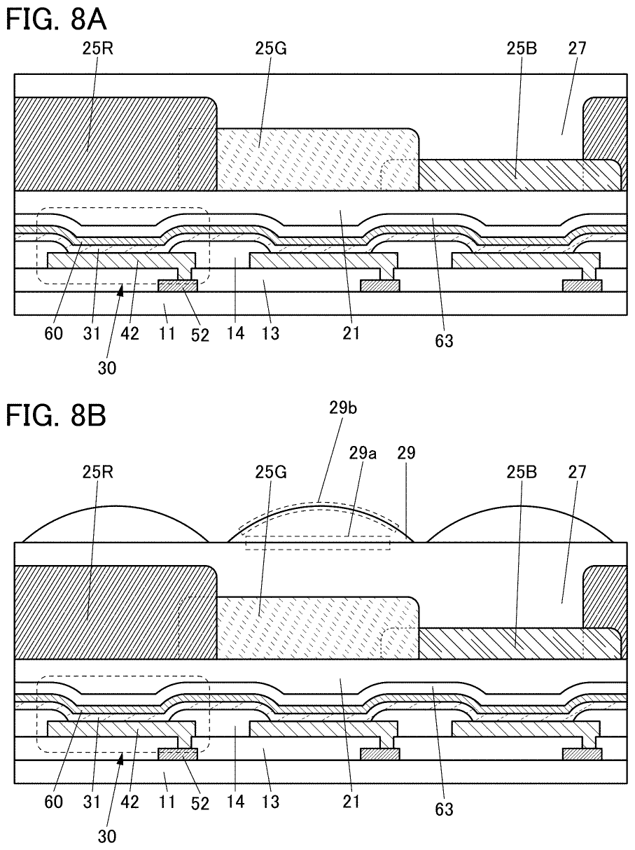

Then, a film to be the planarization layer 27 is formed over the coloring layer 25R, the coloring layer 25G, and the coloring layer 25B. For example, an organic insulating film is formed by a spin coating method or the like (FIG. 8A).

Next, the lens 29 is formed over the planarization layer 27 (FIG. 8B). The lens 29 can be formed in such a manner that a resist pattern is formed by a lithography method, for example, and then the resist is reflowed by heating of the substrate 11.

Then, the substrate 12 is prepared, and the resin layer 33 is formed over the substrate 12. The resin layer 33 can be formed by a screen printing method, a dispensing method, or the like. Next, the lens 29 is attached to the substrate 12 with the resin layer 33. Through the above steps, the display device 10 illustrated in FIG. 1B can be manufactured.

### Structure Example 9

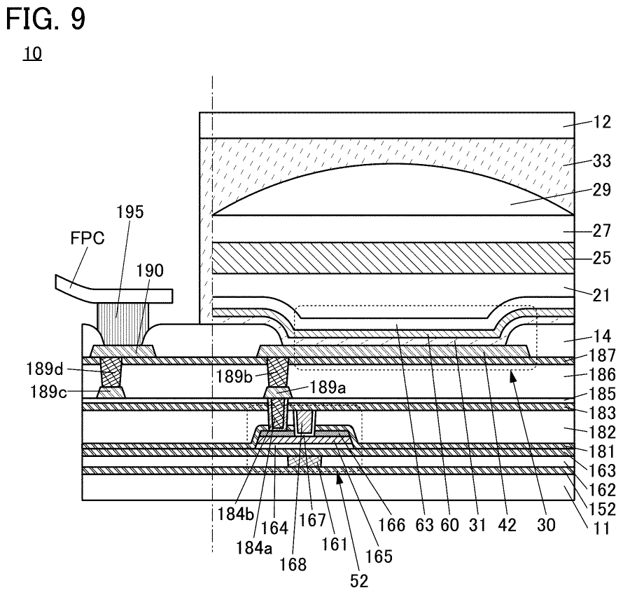

FIG. 9 is a cross-sectional view showing a structure example of the display device 10. FIG. 9 shows is a specific structure example of the display device 10 illustrated in FIG. 1.

In the display device 10 illustrated in FIG. 9, over the substrate 11, an insulating layer 152, the transistor 52, an insulating layer 162, an insulating layer 181, an insulating layer 182, an insulating layer 183, an insulating layer 185, a conductive layer 189a, a conductive layer 189b, a conductive layer 189c, a conductive layer 189d, an insulating layer 186, and an insulating layer 187 are provided. Furthermore, over the insulating layer 187, a conductive layer 190, a conductive layer 195, the light-emitting element 30, the partition 14, the insulating layer 63, the insulating layer 21, the coloring layer 25, the planarization layer 27, the lens 29, the resin layer 33, and the substrate 12 are provided. As described above, the light-emitting element 30 includes the conductive layer 42, the light-emitting layer 31, and the conductive layer 60.

The transistor 52 includes a conductive layer 161, an insulating layer 163, an insulating layer 164, a metal oxide layer 165, a pair of conductive layers 166, an insulating layer 167, a conductive layer 168, and the like. A specific example of a transistor that can be used in the display unit of one embodiment of the present invention, such as the transistor 52, will be described in detail in Embodiment 2.

The metal oxide layer 165 includes a channel formation region. The metal oxide layer 165 includes a first region overlapping with one of the pair of conductive layers 166, a second region overlapping with the other of the pair of conductive layers 166, and a third region between the first region and the second region.

The conductive layer 161 and the insulating layer 162 are provided over the insulating layer 152, and the insulating layer 163 and the insulating layer 164 are provided to cover the conductive layer 161 and the insulating layer 162. The metal oxide layer 165 is provided over the insulating layer 164. The conductive layer 161 functions as a gate electrode, and the insulating layer 163 and the insulating layer 164 function as gate insulating layers. The conductive layer 161 overlaps with the metal oxide layer 165 with the insulating layer 163 and the insulating layer 164 therebetween. The insulating layer 163 preferably functions as a barrier layer like the insulating layer 152. As the insulating layer 164 in contact with the metal oxide layer 165, an oxide insulating film such as a silicon oxide film is preferably used.

Here, the height of the top surface of the conductive layer 161 is substantially the same as the height of the top surface of the insulating layer 162. Thus, the size of the transistor 52 can be reduced.

The pair of conductive layers 166 is provided over the metal oxide layer 165 to be apart from each other. The pair of conductive layers 166 functions as a source and a drain. The insulating layer 181 is provided to cover the metal oxide layer 165 and the pair of conductive layers 166, and the insulating layer 182 is provided over the insulating layer 181. An opening reaching the metal oxide layer 165 is provided in the insulating layer 181 and the insulating layer 182, and the insulating layer 167 and the conductive layer 168 are embedded in the opening. The opening overlaps with the third region. The insulating layer 167 overlaps with a side surface of the insulating layer 181 and a side surface of the insulating layer 182. The conductive layer 168 overlaps with the side surface of the insulating layer 181 and the side surface of the insulating layer 182 with the insulating layer 167 therebetween. The conductive layer 168 functions as a gate electrode, and the insulating layer 167 functions as a gate insulating layer. The conductive layer 168 overlaps with the metal oxide layer 165 with the insulating layer 167 therebetween.

Here, the height of the top surface of the conductive layer 168 is substantially the same as the height of the top surface of the insulating layer 182. Thus, the size of the transistor 52 can be reduced.

An insulating layer 183 and an insulating layer 185 are provided to cover the top surfaces of the insulating layer 182, the insulating layer 167, and the conductive layer 168.

The insulating layer 152, the insulating layer 181, and the insulating layer 183 have a barrier layer function of inhibiting entry of impurities such as water or hydrogen to the metal oxide layer 165 and the release of oxygen from the metal oxide layer 165. When the pair of conductive layers 166 is covered with the insulating layer 181, oxidation of the pair of conductive layers 166 due to oxygen contained in the insulating layer 182 can be inhibited.

As the insulating layer 152, the insulating layer 181, and the insulating layer 183, a film in which hydrogen and oxygen is less likely to be diffused than in a silicon oxide film, such as an aluminum oxide film, a hafnium oxide film, or a silicon nitride film, can be used, for example.

A plug electrically connected to one of the pair of conductive layers 166 and a conductive layer 189a is embedded in an opening provided in the insulating layer 181, the insulating layer 182, the insulating layer 183, and the insulating layer 185. The plug preferably includes a conductive layer 184b in contact with the side surface of the opening and the top surface of one of the pair of conductive layers 166, and a conductive layer 184a embedded inside the conductive layer 184b. In this case, a conductive material in which hydrogen and oxygen are less likely to diffuse is preferably used for the conductive layer 184b.

The conductive layer 189a and an insulating layer 186 are provided over the insulating layer 185, a conductive layer 189b is provided over the conductive layer 189a, and an insulating layer 187 is provided over the insulating layer 186. The insulating layer 186 preferably has a planarization function. Here, the height of the top surface of the conductive layer 189b is substantially the same as the height of the top surface of the insulating layer 187. An opening reaching the conductive layer 189a is provided in the insulating layer 187 and the insulating layer 186, and the conductive layer 189b is embedded in the opening. The conductive layer 189b functions as a plug that electrically connects the conductive layer 189a and the conductive layer 42.

One of the pair of conductive layers 166 of the transistor 52 is electrically connected to the conductive layer 42 included in the light-emitting element 30 through the conductive layer 184a, the conductive layer 184b, the conductive layer 189a, and the conductive layer 189b.

The insulating layer 186 is preferably formed using an inorganic insulating material such as silicon oxide, silicon oxynitride, silicon nitride oxide, silicon nitride, aluminum oxide, hafnium oxide, or titanium nitride.

As the insulating layer 187, a film through which hydrogen and oxygen are less likely to diffuse than through a silicon oxide film, such as an aluminum oxide film, a hafnium oxide film, or a silicon nitride film, can be used, for example. The insulating layer 187 preferably has a barrier layer function of inhibiting entry of impurities such as water or hydrogen to the transistor 52.

The conductive layer 189c is electrically connected to FPC through the conductive layer 189d, the conductive layer 190, and the conductive layer 195. The display device 10 is supplied with a signal and power through FPC.

The conductive layer 189c can be formed using the same material and the same step as the conductive layer 189a. The conductive layer 189d can be formed using the same material and the same step as the conductive layer 189b. The conductive layer 190 can be formed using the same material and the same step as the conductive layer 42.

For the conductive layer 195, for example, an anisotropic conductive film (ACF), an anisotropic conductive paste (ACP), or the like can be used.

At least part of this embodiment can be implemented in appropriate combination with the other embodiments or examples described in this specification.

### Embodiment 2

In this embodiment, a transistor that can be used in the display unit of one embodiment of the present invention will be described.

There is no particular limitation on the structure of the transistor in the display unit. For example, a planar transistor, a staggered transistor, or an inverted staggered transistor may be used. A top-gate transistor or a bottom-gate transistor may be used. Gate electrodes may be provided above and below a channel.

As the transistor of the display unit, a transistor containing metal oxide in a channel formation region can be used, for example. Therefore, a transistor with an extremely low off-state current can be obtained.

As the transistor of the display unit, a transistor containing silicon in a channel formation region may be used. Examples of the transistor include a transistor containing amorphous silicon, a transistor containing crystalline silicon (typically, low-temperature polysilicon), and a transistor containing single crystal silicon. For example, a transistor containing metal oxide in a channel formation region and a transistor containing silicon in a channel formation region may be used in combination.

Note that in this specification and the like, a transistor is an element having at least three terminals: a gate, a drain, and a source. The transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or when a direction of current flow is changed in circuit operation, for example. Therefore, the terms “source” and “drain” can be interchanged in some cases in this specification and the like.

Note that a channel length refers to, for example, a distance between a source (source region or source electrode) and a drain (drain region or drain electrode) in a region where a semiconductor (or a portion where a current flows in a semiconductor when a transistor is on) and a gate electrode overlap each other or in a channel formation region in a top view of the transistor. In one transistor, channel lengths in all regions are not necessarily the same. In other words, the channel length of one transistor is not fixed to one value in some cases. Therefore, in this specification, the channel length is any one of values, the maximum values, the minimum value, or the average value in a channel formation region.

A channel width refers to, for example, the length of a channel formation region perpendicular to a channel length direction in a region where a semiconductor (or a portion where a current flows in a semiconductor when a transistor is on) and a gate electrode overlap with each other or in the channel formation region in a top view of the transistor. In one transistor, channel widths in all regions are not necessarily the same. In other words, the channel width of one transistor is not fixed to one value in some cases. Therefore, in this specification, the channel width is any one of values, the maximum value, the minimum value, or the average value in a channel formation region.

Note that in this specification and the like, depending on the transistor structure, a channel width in a region where a channel is actually formed (hereinafter also referred to as an effective channel width) is different from a channel width shown in a top view of a transistor (hereinafter also referred to as an apparent channel width) in some cases. For example, in a transistor having a gate electrode covering the side surface of a semiconductor, the effective channel width is larger than the apparent channel width, and its influence cannot be ignored in some cases. As another example, in a miniaturized transistor having a gate electrode covering the side surface of a semiconductor, the proportion of a channel formation region formed on the side surface of the semiconductor is sometimes increased. In that case, the effective channel width is larger than the apparent channel width.

In such cases, an effective channel width is sometimes difficult to estimate by measuring. For example, to estimate an effective channel width from a design value, it is necessary to assume that the shape of a semiconductor is known. Accordingly, in the case where the shape of a semiconductor is not known exactly, it is difficult to measure an effective channel width accurately.

In this specification, the simple term “channel width” denotes an apparent channel width in some cases. In other cases, the simple term “channel width” denotes an effective channel width. Note that the values of a channel length, a channel width, an effective channel width, an apparent channel width, and the like can be determined by analyzing a cross-sectional TEM image and the like.

In this specification and the like, the term “insulator” can be replaced with an insulating film or an insulating layer. The term “conductor” can be replaced with a conductive film or a conductive layer. The term “oxide” can be replaced with an oxide film or an oxide layer. The term “semiconductor” can be replaced with a semiconductor film or a semiconductor layer.

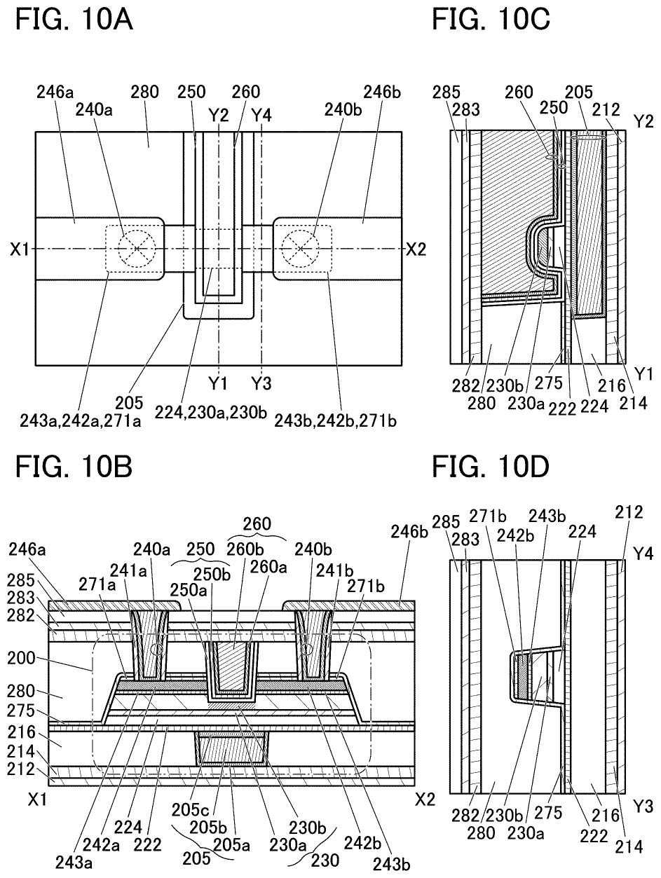

FIG. 10A is a top view of a transistor 200. Note that for simplification, some components are not illustrated in FIG. 10A. FIG. 10B is a cross-sectional view taken along a dashed-dotted line X1-X2 in FIG. 10A. FIG. 10B can also be referred to as a cross-sectional view of the transistor 200 in the channel length direction. FIG. 10C is a cross-sectional view taken along a dashed-dotted line Y1-Y2 in FIG. 10A. FIG. 10C can also be referred to as a cross-sectional view of the transistor 200 in the channel width direction. FIG. 10D is a cross-sectional view taken along a dashed-dotted line Y3-Y4 in FIG. 10A.

The semiconductor device illustrated in FIG. 10A to FIG. 10D includes, an insulator 212 over a substrate (not illustrated), an insulator 214 over the insulator 212, the transistor 200 over the insulator 214, an insulator 280 over the transistor 200, an insulator 282 over the insulator 280, an insulator 283 over the insulator 282, and an insulator 285 over the insulator 283. The insulator 212, the insulator 214, the insulator 280, the insulator 282, the insulator 283, and the insulator 285 each function as an interlayer insulating film. The semiconductor device also includes a conductor 240 (a conductor 240a and a conductor 240b) that is electrically connected to the transistor 200 and functions as a plug. Note that an insulator 241 (an insulator 241a and an insulator 241b) is provided in contact with the side surface of the conductor 240 functioning as a plug. A conductor 246 (a conductor 246a and a conductor 246b) electrically connected to the conductor 240 and functioning as a wiring is provided over the insulator 285 and the conductor 240.

The insulator 241a is provided in contact with an inner wall of an opening formed in the insulator 280, the insulator 282, the insulator 283, and the insulator 285, a first conductor of the conductor 240a is provided in contact with the side surface of the insulator 241a, and a second conductor of the conductor 240a is provided inside the first conductor. The insulator 241b is provided in contact with an inner wall of an opening formed in the insulator 280, the insulator 282, and the insulator 283, and the insulator 285, a first conductor of the conductor 240b is provided in contact with the side surface of the insulator 241b, and a second conductor of the conductor 240b is provided inside the first conductor. The top surface of the conductor 240 can be substantially level with the top surface of the insulator 285 in a region overlapping with the conductor 246. Although the first conductor and the second conductor are stacked as the conductor 240 in the transistor 200, the present invention is not limited thereto. For example, the conductor 240 may have a single-layer structure or a stacked-layer structure of three or more layers. In the case where a stacked-layer structure is employed, the layers may be distinguished by numbers corresponding to the formation order.

### Transistor 200

As illustrated in FIG. 10A to FIG. 10D, the transistor 200 includes an insulator 216 over the insulator 214, a conductor 205 (a conductor 205a, a conductor 205b, and a conductor 205c) provided to be embedded in the insulator 216, an insulator 222 over the insulator 216 and the conductor 205, an insulator 224 over the insulator 222, an oxide 230a over the insulator 224, an oxide 230b over the oxide 230a, an oxide 243 (an oxide 243a and an oxide 243b) over the oxide 230b, a conductor 242a over the oxide 243a, an insulator 271a over the conductor 242a, a conductor 242b over the oxide 243b, an insulator 271b over the conductor 242b, an insulator 250 (an insulator 250a and an insulator 250b) over the oxide 230b, a conductor 260 (a conductor 260a and a conductor 260b) provided over the insulator 250 and overlapping with part of the oxide 230b, and an insulator 275 provided to cover the insulator 222, the insulator 224, the oxide 230a, the oxide 230b, the oxide 243a, the oxide 243b, the conductor 242a, the conductor 242b, the insulator 271a, and insulator 271b.

Hereinafter, the oxide 230a and the oxide 230b are collectively referred to as an oxide 230 in some cases. The conductor 242a and the conductor 242b are collectively referred to as a conductor 242 in some cases. The insulator 271a and the insulator 271b are collectively referred to as an insulator 271 in some cases.

An opening reaching the oxide 230b is provided in the insulator 280 and the insulator 275. The insulator 250 and the conductor 260 are provided in the opening. In addition, in the channel length direction of the transistor 200, the conductor 260 and the insulator 250 are provided between the insulator 271a, the conductor 242a, and the oxide 243a and the insulator 271b, the conductor 242b, and the oxide 243b. The insulator 250 includes a region in contact with the side surface of the conductor 260 and a region in contact with the bottom surface of the conductor 260.

The oxide 230 preferably includes the oxide 230a provided over the insulator 224 and the oxide 230b provided over the oxide 230a. When the oxide 230a is provided under the oxide 230b, impurities can be inhibited from being diffused into the oxide 230b from the components formed below the oxide 230a.

Although the oxide 230 of the transistor 200 has a structure in which two layers, the oxide 230a and the oxide 230b, are stacked, the present invention is not limited to this structure. For example, the oxide 230 may have a single-layer structure of the oxide 230b or a stacked-layer structure of three or more layers, or the oxide 230a and the oxide 230b may each have a stacked-layer structure.

The conductor 260 functions as a first gate (also referred to as a top gate) electrode and the conductor 205 functions as a second gate (also referred to as a back gate) electrode. The insulator 250 functions as a first gate insulating film, and the insulator 224 and the insulator 222 function as a second gate insulating film. The conductor 242a functions as one of a source electrode and a drain electrode, and the conductor 242b functions as the other of the source electrode and the drain electrode. A region of the oxide 230 that overlaps with the conductor 260 at least partly functions as a channel formation region.

A region of the oxide 230b that overlaps with the conductor 242a includes one of source and drain regions, and a region of the oxide 230b that overlaps with the conductor 242b includes the other of the source and drain regions. A region of the oxide 230b that is interposed between the source and drain regions includes a channel formation region (a region indicated by a shaded portion in FIG. 10B).

The channel formation region has a smaller amount of oxygen vacancies or a lower impurity concentration than the source and drain regions, and thus has a low carrier concentration and a high resistance. Here, the carrier concentration of the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. Note that the lower limit of the carrier concentration of the channel formation region is not particularly limited and can be, for example, 1×10⁻⁹ cm⁻³.

Although the channel formation region, the source region, and the drain region are formed in the oxide 230b in the above-described example, the present invention is not limited thereto. For example, a channel formation region, a source region, and a drain region are also formed in the oxide 230a in some cases.

In the transistor 200, the oxide 230 (the oxide 230a and the oxide 230b), which includes the channel formation region, is preferably formed using metal oxide functioning as a semiconductor (hereinafter referred to as an oxide semiconductor).

The metal oxide functioning as a semiconductor preferably has a band gap of 2 eV or more, preferably 2.5 eV or more. The use of such metal oxide having a wide band gap can reduce the off-state current of the transistor.

For example, as the oxide 230, metal oxide such as an In-M-Zn oxide containing indium, an element M, and zinc is used; the element M is one or more selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like. Alternatively, In—Ga oxide, In—Zn oxide, or indium oxide may be used as the oxide 230.

Here, the atomic ratio of In to the element Min the metal oxide used as the oxide 230b is preferably greater than that in the metal oxide used as the oxide 230a.

Specifically, as the oxide 230a, metal oxide having an atomic ratio of In:M:Zn=1:3:4 or in the vicinity thereof, or In:M:Zn=1:1:0.5 or in the vicinity thereof may be used. As the oxide 230b, a metal oxide having an atomic ratio of In:M:Zn=1:1:1 or in the vicinity thereof or In:M:Zn=4:2:3 or in the vicinity thereof may be used. Note that the vicinity of the atomic ratio includes ±30% of an intended atomic ratio. Gallium is preferably used as the element M.

When the metal oxide is deposited by a sputtering method, the aforementioned atomic ratio is not limited to the atomic ratio of the deposited metal oxide and may be the atomic ratio of a sputtering target used for depositing the metal oxide.

When the oxide 230a is provided under the oxide 230b in the above manner, impurities and oxygen can be inhibited from diffusing into the oxide 230b from the components formed below the oxide 230a.

Furthermore, when the oxide 230a and the oxide 230b contain a common element (as the main component) besides oxygen, the density of defect states at the interface between the oxide 230a and the oxide 230b can be low. Since the density of defect states at the interface between the oxide 230a and the oxide 230b can be low, the influence of interface scattering on carrier conduction can be small and a high on-state current can be obtained.

The oxide 230a and the oxide 230b preferably have crystallinity. In particular, as the oxide 230b, a c-axis aligned crystalline oxide semiconductor (CAAC-OS) is preferably used.

The CAAC-OS is a metal oxide having a dense structure with high crystallinity and a small amount of impurities and defects (oxygen vacancy (Vo) or the like). In particular, after the formation of a metal oxide, heat treatment is performed at a temperature at which the metal oxide does not become a polycrystal (e.g., 400° C. to 600° C. inclusive), whereby a CAAC-OS having a dense structure with higher crystallinity can be obtained. As the density of the CAAC-OS is increased in such a manner, diffusion of impurities or oxygen in the CAAC-OS can be further reduced.

By contrast, in the CAAC-OS, a reduction in electron mobility due to a grain boundary is less likely to occur because it is difficult to observe a clear grain boundary. Thus, a metal oxide including the CAAC-OS is physically stable. Accordingly, the metal oxide including the CAAC-OS is resistant to heat and has high reliability.

At least one of the insulator 212, the insulator 214, the insulator 271, the insulator 275, the insulator 282, and the insulator 283 preferably functions as a barrier insulating film that inhibits diffusion of impurities such as water and hydrogen from the substrate side or from above the transistor 200 into the transistor 200. Thus, at least one of the insulator 212, the insulator 214, the insulator 271, the insulator 275, the insulator 282, and the insulator 283 is preferably formed using an insulating material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms, that is, an insulating material through which the impurities are less likely to pass. Alternatively, it is preferable to use an insulating material having a function of inhibiting diffusion of oxygen (e.g., at least one of oxygen atoms, oxygen molecules, and the like), that is, an insulating material through which the above oxygen is less likely to pass.

Note that in this specification, a barrier insulating film refers to an insulating film having a barrier property. A barrier property in this specification refers to a function of inhibiting diffusion of a particular substance (also referred to as a function of less easily transmitting the substance). Alternatively, a barrier property in this specification refers to a function of capturing and fixing (also referred to as gettering) a particular substance.

Aluminum oxide, magnesium oxide, hafnium oxide, gallium oxide, indium gallium zinc oxide, silicon nitride, or silicon nitride oxide can be used for the insulator 212, the insulator 214, the insulator 271, the insulator 275, the insulator 282, and the insulator 283, for example. For example, silicon nitride, which has a high hydrogen barrier property, is preferably used for the insulator 212, the insulator 275, and the insulator 283. For example, aluminum oxide, magnesium oxide, or the like, which has an excellent function of capturing and fixing hydrogen, is preferably used for the insulator 214, the insulator 271, and the insulator 282. Accordingly, impurities such as water and hydrogen can be inhibited from diffusing from the substrate side to the transistor 200 side through the insulator 212 and the insulator 214. Furthermore, impurities such as water and hydrogen can be inhibited from diffusing to the transistor 200 side from an interlayer insulating film and the like positioned outside the insulator 283. In addition, oxygen contained in the insulator 224 and the like can be inhibited from diffusing to the substrate side through the insulator 212 and the insulator 214. Oxygen contained in the insulator 280 and the like can be inhibited from diffusing to the components over the transistor 200 through the insulator 282 and the like. In this manner, the transistor 200 is preferably surrounded by the insulator 212, the insulator 214, the insulator 271, the insulator 275, the insulator 282, and the insulator 283, which have a function of inhibiting diffusion of oxygen and impurities such as water and hydrogen.

Here, oxide having an amorphous structure is preferably used as the insulator 212, the insulator 214, the insulator 271, the insulator 275, the insulator 282, and the insulator 283. For example, metal oxide such as AlOₓ (x is a given number larger than 0) or MgO_{y} (y is a given number larger than 0) is preferably used. In such metal oxide having an amorphous structure, oxygen atoms have dangling bonds, and the metal oxide has a property of capturing or fixing hydrogen with the dangling bonds in some cases. When such metal oxide having an amorphous structure is used as the component of the transistor 200 or provided in the vicinity of the transistor 200, hydrogen contained in the transistor 200 or hydrogen in the vicinity of the transistor 200 can be captured or fixed. In particular, hydrogen contained in the channel formation region of the transistor 200 is preferably captured or fixed. The metal oxide having an amorphous structure is used as the component of the transistor 200 or provided in the vicinity of the transistor 200, whereby the transistor 200 and the semiconductor device with favorable characteristics and high reliability can be manufactured.

Although the insulator 212, the insulator 214, the insulator 271, the insulator 275, the insulator 282, and the insulator 283 preferably have an amorphous structure, they may include a region having a polycrystalline structure. Alternatively, the insulator 212, the insulator 214, the insulator 271, the insulator 275, the insulator 282, and the insulator 283 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 271, the insulator 275, the insulator 282, and the insulator 283 can be deposited by a sputtering method, for example. Since a sputtering method does not need to use hydrogen as a deposition gas, the hydrogen concentrations of the insulator 212, the insulator 214, the insulator 271, the insulator 275, the insulator 282, and the insulator 283 can be reduced. Note that the deposition method is not limited to a sputtering method, and a CVD method, an MBE method, a PLD method, an ALD method, or the like can be used as appropriate.

The dielectric constants of the insulator 216, the insulator 280, and the insulator 285 are preferably lower than that of the insulator 214. The use of a material having a low dielectric constant for the interlayer insulating film can reduce the parasitic capacitance between wirings. For example, for the insulator 216, the insulator 280, and the insulator 285, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate.

The conductor 205 is provided to overlap with the oxide 230 and the conductor 260. Here, the conductor 205 is preferably provided to fill an opening formed in the insulator 216.

The conductor 205 includes the conductor 205a, the conductor 205b, and the conductor 205c. The conductor 205a is provided in contact with the bottom surface and the side wall of the opening. The conductor 205b is provided so as to be embedded in a recessed portion formed in the conductor 205a. Here, the height of the top surface of the conductor 205b is lower than the levels of the top surface of the conductor 205a and the top surface of the insulator 216. The conductor 205c is provided in contact with the top surface of the conductor 205b and the side surface of the conductor 205a. Here, the height of the top surface of the conductor 205c is substantially the same as the top surface of the conductor 205a and the height of the top surface of the insulator 216. That is, the conductor 205b is surrounded by the conductor 205a and the conductor 205c.

A conductive material that can be used for the conductor 260a described later may be used for the conductor 205a and the conductor 205c. A conductive material that can be used for the conductor 260b described later may be used for the conductor 205b. Although the conductor 205 of the transistor 200 has a structure in which the conductor 205a, the conductor 205b, and the conductor 205c are stacked, the present invention is not limited to this structure. For example, the conductor 205 may have a single-layer structure or a stacked-layer structure of two layers or four or more layers.

The insulator 222 and the insulator 224 function as a gate insulating film.

The insulator 222 preferably has a function of inhibiting diffusion of hydrogen (e.g., at least one of hydrogen atoms, hydrogen molecules, and the like). Moreover, the insulator 222 preferably has a function of inhibiting diffusion of oxygen (e.g., at least one of oxygen atoms, oxygen molecules, and the like). For example, the insulator 222 preferably has a function of inhibiting diffusion of much hydrogen and/or oxygen compared to the insulator 224.

As the insulator 222, an insulator containing an oxide of one or both of aluminum and hafnium, which is an insulating material, is preferably used. As the insulator, aluminum oxide, hafnium oxide, an oxide containing aluminum and hafnium (hafnium aluminate), or the like is preferably used. As the insulator 222, a barrier insulating film that can be used as the insulator 214 or the like may be used.

Silicon oxide, silicon oxynitride, or the like can be used as appropriate for the insulator 224. When the insulator 224 containing oxygen is provided in contact with the oxide 230, oxygen vacancies in the oxide 230 can be reduced, leading to an improvement in the reliability of the transistor 200. The insulator 224 is preferably processed into an island shape so as to overlap with the oxide 230a. In that case, the insulator 275 is in contact with the side surface of the insulator 224 and the top surface of the insulator 222. Accordingly, the insulator 224 and the insulator 280 can be apart from each other by the insulator 275; thus, diffusion of oxygen contained in the insulator 280 into the insulator 224 can be reduced, so that the amount of oxygen in the insulator 224 can be prevented from being excessively large.

Note that the insulator 222 and the insulator 224 may each have a stacked-layer structure of two or more layers. In that case, the stacked layers are not necessarily formed of the same material and may be formed of different materials. Note that FIG. 10B and the like illustrates the structure in which the insulator 224 is formed into an island shape so as to overlap with the oxide 230a; however, the present invention is not limited to this structure. In the case where the amount of oxygen contained in the insulator 224 can be adjusted appropriately, a structure in which the insulator 224 is not pattered in a manner similar to that of the insulator 222 may be employed.

The oxide 243a and the oxide 243b are provided over the oxide 230b. The oxide 243a and the oxide 243b are provided to be apart from each other with the conductor 260 therebetween. The oxide 243 (the oxide 243a and the oxide 243b) preferably has a function of inhibiting oxygen transmission. It is preferable that the oxide 243 having a function of inhibiting oxygen transmission be provided between the oxide 230b and the conductor 242 functioning as the source electrode or the drain electrode, in which case the electrical resistance between the oxide 230b and the conductor 242 is reduced. In the case where the electrical resistance between the oxide 230b and the conductor 242 can be sufficiently reduced, the oxide 243 is not necessarily provided.

Metal oxide containing the element M may be used as the oxide 243. In particular, aluminum, gallium, yttrium, or tin is preferably used as the element M. The concentration of the element M in the oxide 243 is preferably higher than that in the oxide 230b. Alternatively, gallium oxide may be used as the oxide 243. A metal oxide such as an In-M-Zn oxide may be used as the oxide 243. Specifically, the atomic ratio of the element M to In in the metal oxide used as the oxide 243 is preferably higher than that in the metal oxide used as the oxide 230b. The thickness of the oxide 243 is preferably greater than or equal to 0.5 nm and less than or equal to 5 nm, further preferably greater than or equal to 1 nm and less than or equal to 3 nm, still further preferably greater than or equal to 1 nm and less than or equal to 2 nm.

It is preferable that the conductor 242a be provided in contact with the top surface of the oxide 243a and the conductor 242b be provided in contact with the top surface of the oxide 243b. The conductor 242a and the conductor 242b function as the source electrode and the drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are a conductive material that is not easily oxidized or a material that maintains the conductivity even when absorbing oxygen.

No curved surface is preferably formed between the side surface of the conductor 242 and the top surface of the conductor 242. Without the curved surface, the conductor 242 can have a large cross-sectional area in the channel width direction as illustrated in FIG. 10D. Accordingly, the conductivity of the conductor 242 is increased, so that the on-state current of the transistor 200 can be increased.

The insulator 271a is provided in contact with the top surface of the conductor 242a, and the insulator 271b is provided in contact with the top surface of the conductor 242b.

The insulator 275 is provided in contact with the top surface of the insulator 222, the side surface of the insulator 224, the side surface of the oxide 230a, the side surface of the oxide 230b, the side surface of the oxide 243, the side surface of the conductor 242, and the top and side surfaces of the insulator 271. An opening is provided in a region of the insulator 275 where the insulator 250 and the conductor 260 are provided.

The insulator 214, the insulator 271, and the insulator 275 having a function of capturing impurities such as hydrogen are provided in a region interposed between the insulator 212 and the insulator 280, whereby impurities such as hydrogen contained in the insulator 224, the insulator 216, or the like can be captured, and the amount of hydrogen in the region can be kept constant. In that case, the insulator 214, the insulator 271, and the insulator 275 preferably contain aluminum oxide with an amorphous structure.

The insulator 250 includes the insulator 250a and the insulator 250b over the insulator 250a and functions as a gate insulating film. It is preferable that the insulator 250a be provided in contact with the top surface of the oxide 230b, the side surface of the oxide 243, the side surface of the conductor 242, the side surface of the insulator 271, the side surface of the insulator 275, and the side surface of the insulator 280. The thickness of the insulator 250 is preferably greater than or equal to 1 nm and less than or equal to 20 nm.

For the insulator 250a, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like can be used. In particular, silicon oxide and silicon oxynitride, which have thermal stability, are preferable. As in the insulator 224, for the insulator 250a, the concentration of impurities such as water, hydrogen, and the like in the insulator 250a is preferably reduced.

It is preferable that the insulator 250a be formed using an insulator from which oxygen is released by heating and the insulator 250b be formed using an insulator having a function of inhibiting diffusion of oxygen. Owing to this structure, diffusion of oxygen contained in the insulator 250a into the conductor 260 can be inhibited. That is, a reduction in the amount of oxygen supplied to the oxide 230 can be inhibited. Moreover, oxidation of the conductor 260 due to oxygen contained in the insulator 250a can be inhibited. For example, the insulator 250b can be formed using a material similar to that used for the insulator 222.

Specifically, for the insulator 250b, metal oxide containing one or more of hafnium, aluminum, gallium, yttrium, zirconium, tungsten, titanium, tantalum, nickel, germanium, magnesium, and the like or metal oxide that can be used as the oxide 230 can be used. In particular, an insulator containing oxide of one or both of aluminum and hafnium is preferably used. As the insulator, aluminum oxide, hafnium oxide, oxide containing aluminum and hafnium (hafnium aluminate), or the like is preferably used. The thickness of the insulator 250b is preferably greater than or equal to 0.5 nm and less than or equal to 3.0 nm, further preferably greater than or equal to 1.0 nm and less than or equal to 1.5 nm.

Although FIG. 10B and FIG. 10C show that the insulator 250 has the stacked-layer structure of two layers, the present invention is not limited thereto. The insulator 250 may have a single-layer structure or a stacked-layer structure of three or more layers.

The conductor 260 is provided over the insulator 250b and functions as a first gate electrode of the transistor 200. The conductor 260 preferably includes the conductor 260a and the conductor 260b over the conductor 260a. For example, the conductor 260a is preferably positioned so as to cover the bottom and side surfaces of the conductor 260b. As illustrated in FIG. 10B and FIG. 10C, the top surface of the conductor 260 is substantially aligned with the top surface of the insulator 250. Although FIG. 10B and FIG. 10C show that the conductor 260 has the two-layer structure of the conductor 260a and the conductor 260b, the conductor 260 may have a single-layer structure or a stacked-layer structure of three or more layers.

The conductor 260a is preferably formed using a conductive material having a function of inhibiting diffusion of impurities such as hydrogen atoms, hydrogen molecules, water molecules, nitrogen atoms, nitrogen molecules, nitrogen oxide molecules, and copper atoms. Alternatively, the conductor 260a is preferably formed using a conductive material having a function of inhibiting diffusion of oxygen (e.g., at least one of oxygen atoms and oxygen molecules).

When the conductor 260a has a function of inhibiting diffusion of oxygen, the conductivity of the conductor 260b can be prevented from being lowered because of oxidization of the conductor 260b due to oxygen in the insulator 250. As the conductive material having a function of inhibiting diffusion of oxygen, for example, titanium, titanium nitride, tantalum, tantalum nitride, ruthenium, or ruthenium oxide is preferably used.

The conductor 260 also functions as a wiring and thus is preferably a conductor having high conductivity. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor 200, the conductor 260 is formed in a self-aligned manner so as to fill an opening formed in the insulator 280 and the like. Being formed in this manner, the conductor 260 can surely be provided in a region between the conductor 242a and the conductor 242b without alignment.

In the channel width direction of the transistor 200 as illustrated in FIG. 10C, with the level of the bottom surface of the insulator 222 as a reference, the level of the bottom surface of the conductor 260 in a region where the conductor 260 and the oxide 230b do not overlap is preferably lower than the level of the bottom surface of the oxide 230b. When the conductor 260 functioning as the gate electrode covers the side surface and the top surface of the channel formation region of the oxide 230b with the insulator 250 and the like therebetween, the electric field of the conductor 260 is likely to affect the entire channel formation region in the oxide 230b. Hence, the transistor 200 can have a higher on-state current and higher frequency characteristics. With the level of the bottom surface of the insulator 222 as a reference, a distance between the bottom surface of the conductor 260 and the bottom surfaces of the oxide 230b in a region where the conductor 260 does not overlap with the oxide 230a and the oxide 230b is greater than or equal to 0 nm and less than or equal to 100 nm, preferably greater than or equal to 3 nm and less than or equal to 50 nm, and further preferably greater than or equal to 5 nm and less than or equal to 20 nm.

The insulator 280 is provided over the insulator 275, and the opening is formed in the region where the insulator 250 and the conductor 260 are provided. The top surface of the insulator 280 may be planarized. In that case, the top surface of the insulator 280 is preferably aligned with the top surface of the insulator 250 and the top surface of the conductor 260.

The insulator 282 is provided in contact with the top surface of the insulator 280, the top surface of the insulator 250, and the top surface of the conductor 260. The insulator 282 preferably functions as a barrier insulating film that inhibits impurities such as water and hydrogen from diffusing into the insulator 280 from the above and also has a function of capturing impurities such as hydrogen. The insulator 282 also preferably functions as a barrier insulating film that inhibits oxygen transmission. As the insulator 282, for example, an insulator such as aluminum oxide can be used. The insulator 282, which has a function of capturing impurities such as hydrogen, is provided in contact with the insulator 280 in a region interposed between the insulator 212 and the insulator 283, whereby impurities such as hydrogen contained in the insulator 280 and the like can be captured and the amount of hydrogen in the region can be kept constant. It is particularly preferable to use aluminum oxide having an amorphous structure as the insulator 282 because hydrogen can be captured or fixed more effectively in some cases. Accordingly, the transistor 200 and the semiconductor device with favorable characteristics and high reliability can be manufactured.

The conductor 240a and the conductor 240b are preferably formed using a conductive material containing tungsten, copper, or aluminum as the main component. The conductor 240a and the conductor 240b may have a stacked-layer structure. In the case where the conductor 240 has a stacked-layer structure, the conductor in contact with the insulator 241 is preferably formed using a conductive material having a function of inhibiting transmission of impurities such as water and hydrogen. For example, any of the above conductive materials that can be used for the conductor 260a may be used.

An insulator such as silicon nitride, aluminum oxide, or silicon nitride oxide may be used as the insulator 241a and the insulator 241b, for example. Since the insulator 241a and the insulator 241b are provided in contact with the insulator 283, the insulator 282, and the insulator 271, impurities such as water and hydrogen contained in the insulator 280 and the like can be prevented from entering the oxide 230 through the conductor 240a and the conductor 240b.

The conductor 246 (the conductor 246a and the conductor 246b) functioning as a wiring may be provided in contact with the top surface of the conductor 240a and the top surface of the conductor 240b. The conductor 246 is preferably formed using a conductive material containing tungsten, copper, or aluminum as its main component. The conductor may have a stacked-layer structure, for example, a stack of titanium or titanium nitride and the above conductive material. Note that the conductor may be formed to be provided to fill an opening in an insulator.

In the above manner, a semiconductor device having favorable electrical characteristics can be provided. A highly reliable semiconductor device can also be provided. A semiconductor device that can be miniaturized or highly integrated can be provided. Alternatively, a semiconductor device with low power consumption can be provided.

### Metal Oxide

Next, metal oxide that can be used for the transistor (also referred to as an oxide semiconductor) will be described.

### Classification of Crystal Structure

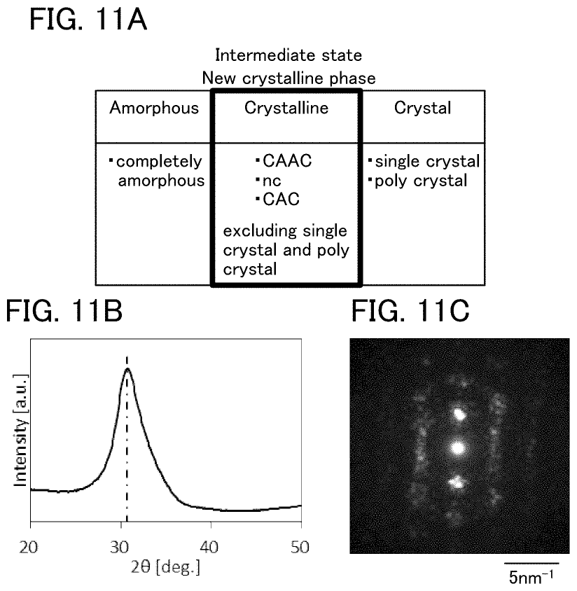

First, the classification of the crystal structures of an oxide semiconductor will be described with reference to FIG. 11A. FIG. 11A is a diagram showing the classification of crystal structures of an oxide semiconductor, typically IGZO (a metal oxide containing In, Ga, and Zn).

As shown in FIG. 11A, an oxide semiconductor is roughly classified into “Amorphous,” “Crystalline,” and “Crystal.” The term “Amorphous” includes completely amorphous. The term “Crystalline” includes CAAC, nc (nanocrystalline), and CAC (cloud-aligned composite). Note that the term “Crystalline” excludes single crystal, poly crystal, and completely amorphous. The term “Crystal” includes single crystal and poly crystal.

Note that the structures in the thick frame in FIG. 11A are in an intermediate state between “Amorphous” and “Crystal,” and belong to a new crystalline phase. That is, these structures are completely different from “Amorphous,” which is energetically unstable, and “Crystal.”

A crystal structure of a film or a substrate can be evaluated with an X-ray diffraction (XRD) spectrum. FIG. 11B shows an XRD spectrum, which is obtained by GIXD (Grazing-Incidence XRD) measurement, of a CAAC-IGZO film classified into “Crystalline.” Note that a GIXD method is also referred to as a thin film method or a Seemann-Bohlin method. The XRD spectrum that is shown in FIG. 11B and obtained by GIXD measurement is hereinafter simply referred to as an XRD spectrum. The CAAC-IGZO film in FIG. 11B has a composition in the vicinity of In:Ga:Zn=4:2:3 [atomic ratio]. The CAAC-IGZO film in FIG. 11B has a thickness of 500 nm.

As shown in FIG. 11B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 11B, the peak at 2θ of around 31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 11C shows a diffraction pattern of the CAAC-IGZO film. FIG. 11C shows a diffraction pattern obtained with the NBED method in which an electron beam is incident in the direction parallel to the substrate. The composition of the CAAC-IGZO film in FIG. 11C is In:Ga:Zn=4:2:3 [atomic ratio] or the neighborhood thereof In the nanobeam electron diffraction method, electron diffraction is performed with a probe diameter of 1 nm.

As shown in FIG. 11C, a plurality of spots indicating c-axis alignment are observed in the diffraction pattern of the CAAC-IGZO film.

### Oxide Semiconductor Structure

Oxide semiconductors might be classified in a manner different from the one in FIG. 11A when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS will be described in detail.

### CAAC-OS

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

Furthermore, in an In-M-Zn oxide (the element M is one or more of aluminum, gallium, yttrium, tin, titanium, and the like), the CAAC-OS tends to have a layered crystal structure (also referred to as a layered structure) in which a layer containing indium (In) and oxygen (hereinafter, In layer) and a layer containing the element M, zinc (Zn), and oxygen (hereinafter, (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at or around 2θ=31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are symmetric with respect to a spot of the incident electron beam which passes through a sample (also referred to as a direct spot).

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called a polycrystal structure. It is highly probable that the grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is less likely to occur. Entry of impurities, formation of defects, and the like might decrease the crystallinity of an oxide semiconductor. This means that the CAAC-OS can be referred to as an oxide semiconductor having small amounts of impurities and defects (e.g., oxygen vacancies). Therefore, an oxide semiconductor including the CAAC-OS is physically stable. Accordingly, the oxide semiconductor including the CAAC-OS is resistant to heat and has high reliability. In addition, the CAAC-OS is stable with respect to high temperatures in the manufacturing process (i.e., thermal budget). Accordingly, the use of the CAAC-OS for the OS transistor can extend a degree of freedom of the manufacturing process.

### nc-OS

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. There is no regularity of crystal orientation between different nanocrystals in the nc-OS. Hence, the orientation in the whole film is not observed. Accordingly, in some cases, the nc-OS cannot be distinguished from an a-like OS and/or an amorphous oxide semiconductor, depending on an analysis method. For example, when an nc-OS film is subjected to structural analysis by out-of-plane XRD measurement with an XRD apparatus using θ/2θ scanning, a peak indicating crystallinity is not observed. Furthermore, a halo pattern is shown in a selected-area electron diffraction pattern of the nc-OS film obtained using an electron beam having a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., 1 nm or larger and 30 nm or smaller).

### a-Like OS

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration than the nc-OS and the CAAC-OS.

### Oxide Semiconductor Structure

Next, the CAC-OS will be described in detail. Note that the CAC-OS relates to the material composition.

### CAC-OS

The CAC-OS has, for example, a composition in which elements included in a metal oxide are unevenly distributed. Materials including unevenly distributed elements each have a size greater than or equal to 0.5 nm and less than or equal to 10 nm, preferably greater than or equal to 1 nm and less than or equal to 3 nm, or a similar size. Note that in the following description of a metal oxide, a state in which one or more types of metal elements are unevenly distributed and regions including the metal element(s) are mixed is referred to as a mosaic pattern or a patch-like pattern. The regions each have a size greater than or equal to 0.5 nm and less than or equal to 10 nm, preferably greater than or equal to 1 nm and less than or equal to 3 nm, or a similar size.

In addition, the CAC-OS has a composition in which materials are separated into a first region and a second region to form a mosaic pattern, and the first regions are distributed in the film. This composition is hereinafter also referred to as a cloud-like composition. That is, the CAC-OS is a composite metal oxide having a composition in which the first regions and the second regions are mixed.

Here, the atomic ratios of In, Ga, and Zn to a metal element included in a CAC-OS in an In—Ga—Zn oxide are expressed as [In], [Ga], and [Zn], respectively. For example, the first region in the CAC-OS in the In—Ga—Zn oxide has [In] higher than that in the composition of the CAC-OS film. In addition, the second region of the CAC-OS in the In—Ga—Zn oxide has [Ga], which is greater than that in the composition of the CAC-OS film. Alternatively, for example, [In] of the first region is greater than that in the second region, and [Ga] of the first region is less than that in the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a composition in which the regions containing In as a main component (the first regions) and the regions containing Ga as a main component (the second regions) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when a CAC-OS is used for a transistor, a high on-state current (Iₒₙ), a high field-effect mobility (μ), and favorable switching operation can be achieved.

An oxide semiconductor can have any of various structures that show various different properties. Two or more of the amorphous oxide semiconductor, the polycrystalline oxide semiconductor, the a-like OS, the CAC-OS, the nc-OS, and the CAAC-OS may be included in an oxide semiconductor of one embodiment of the present invention.

### Transistor Including Oxide Semiconductor

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³ and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charges trapped by the trap states in an oxide semiconductor take a long time to be released and may behave like fixed charges. A transistor whose channel formation region is formed in an oxide semiconductor having a high density of trap states has unstable electrical characteristics in some cases.

In order to obtain stable electrical characteristics of the transistor, it is effective to reduce the impurity concentration in the oxide semiconductor. In order to reduce the impurity concentration in the oxide semiconductor, the impurity concentration in an adjacent film is preferably reduced. Examples of impurities include hydrogen, nitrogen, alkali metal, alkaline earth metal, iron, nickel, and silicon.

### Impurity

The influence of impurities in the oxide semiconductor is described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by SIMS) are each set lower than or equal to 2×10¹⁸ atoms/cm³, preferably lower than or equal to 2×10¹⁷ atoms/cm³.

When the oxide semiconductor contains alkali metal or alkaline earth metal, defect states are formed and carriers are generated in some cases. Accordingly, a transistor including an oxide semiconductor that contains alkali metal or alkaline earth metal tends to have normally-on characteristics. Thus, the concentration of alkali metal or alkaline earth metal in the oxide semiconductor, which is obtained by SIMS, is set lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. A transistor including, as a semiconductor, an oxide semiconductor containing nitrogen tends to have normally-on characteristics. When nitrogen is contained in the oxide semiconductor, a trap state is sometimes formed. This might make the electrical characteristics of the transistor unstable. Thus, the nitrogen concentration in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus causes an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor including an oxide semiconductor containing hydrogen tends to have normally-on characteristics. For this reason, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, stable electrical characteristics can be given.

At least part of this embodiment can be implemented in combination with the other embodiments or examples described in this specification as appropriate.

### Embodiment 3

In this embodiment, electronic devices each including a display device of one embodiment of the present invention are described.

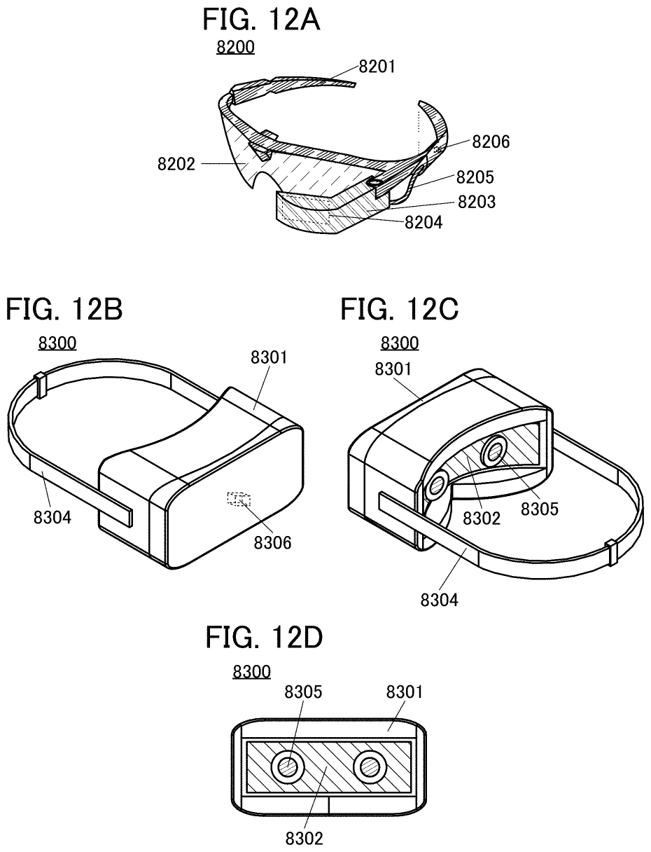

FIG. 12A is a diagram illustrating the appearance of a head-mounted display 8200.

The head-mounted display 8200 includes a wearing portion 8201, a lens 8202, a main body 8203, a display surface 8204, a cable 8205, and the like. A battery 8206 is incorporated in the wearing portion 8201.

The cable 8205 supplies electric power from the battery 8206 to the main body 8203. The main body 8203 includes a wireless receiver or the like and can display an image corresponding to the received image data or the like on the display surface 8204. The movement of the eyeball or the eyelid of the user is captured by a camera provided in the main body 8203 and then coordinates of the sight line of the user are calculated using the information to utilize the sight line of the user as an input means.

A plurality of electrodes may be provided in the wearing portion 8201 at a position in contact with the user. The main body 8203 may have a function of sensing current flowing through the electrodes along with the movement of the user's eyeball to recognize the user's sight line. The main body 8203 may have a function of sensing current flowing through the electrodes to monitor the user's pulse. The wearing portion 8201 may include various sensors such as a temperature sensor, a pressure sensor, and an acceleration sensor to have a function of displaying the user's biological information on the display surface 8204. The main body 8203 may sense the movement of the user's head or the like to change an image displayed on the display surface 8204 in synchronization with the movement.

The display device of one embodiment of the present invention can be used for the display surface 8204. Thus, the user of the head-mounted display 8200 can see a bright image. Furthermore, minute pixels can be provided in the display surface 8204.

FIG. 12B, FIG. 12C, and FIG. 12D are diagrams illustrating the appearance of a head-mounted display 8300. The head-mounted display 8300 includes a housing 8301, a display surface 8302, a band-shaped wearing portion 8304, and a pair of lenses 8305. A battery 8306 is incorporated in the housing 8301, and electric power can be supplied from the battery 8306 to the display surface 8302 or the like.

The user can see display on the display surface 8302 through the lenses 8305. It is suitable that the display surface 8302 be curved and placed. When the display surface 8302 is curved and placed, the user can feel a high realistic sensation. Note that although the structure in which one display surface 8302 is provided is described in this embodiment as an example, the structure is not limited thereto, and a structure in which two display surfaces 8302 are provided may also be employed. In that case, one display surface is placed for one eye of the user, so that three-dimensional display using parallax or the like is possible.

Note that the display device of one embodiment of the present invention can be used for the display surface 8302. Thus, the user of the head-mounted display 8300 can see a bright image. Furthermore, minute pixels can be provided in the display surface 8302.

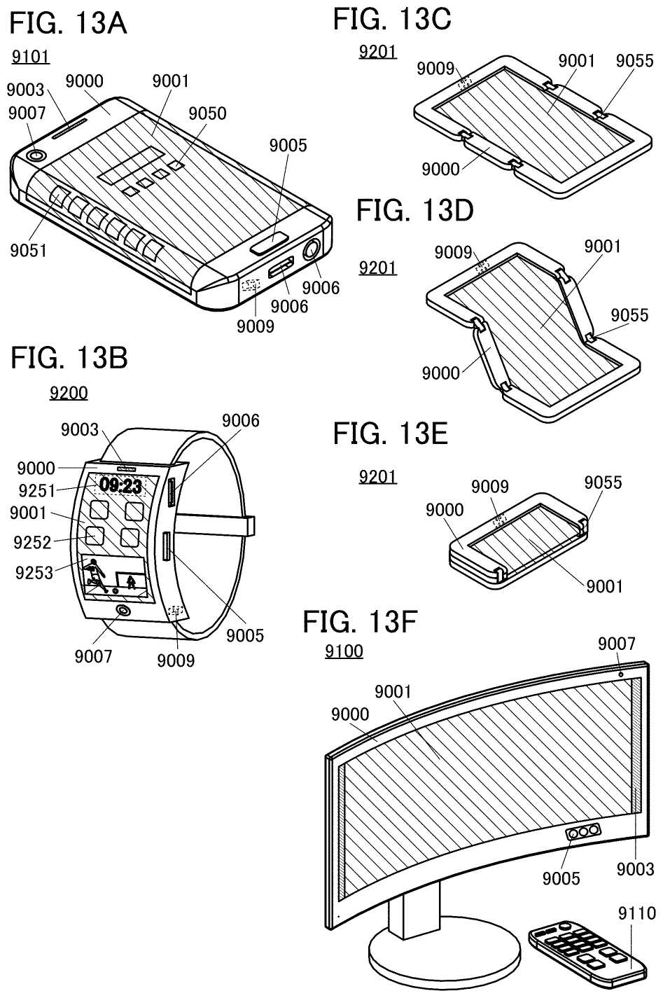

Next, FIG. 13A to FIG. 13F illustrate examples of electronic devices that are different from the electronic devices illustrated in FIG. 12A to FIG. 12D.

Electronic devices illustrated in FIG. 13A to FIG. 13F include a housing 9000, a display surface 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a battery 9009, and the like.

The electronic devices illustrated in FIG. 13A to FIG. 13F have a variety of functions. Examples include a function of displaying a variety of information (a still image, a moving image, a text image, and the like) on the display surface, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a memory medium and displaying it on the display surface. Note that functions of the electronic devices illustrated in FIG. 13A to FIG. 13F are not limited thereto, and the electronic devices can have a variety of functions. Although not illustrated in FIG. 13A to FIG. 13F, the electronic devices may each include a plurality of display surfaces. The electronic devices may each include a camera and the like and have a function of taking a still image, a function of taking a moving image, a function of storing the taken image in a memory medium (external or incorporated in the camera), a function of displaying the taken image on the display surface, and the like.

The details of the electronic devices illustrated in FIG. 13A to FIG. 13F will be described below.

FIG. 13A is a perspective view illustrating a portable information terminal 9101. The portable information terminal 9101 has one or more functions selected from a telephone set, a notebook, an information browsing device, and the like, for example. Specifically, the portable information terminal 9101 can be used as a smartphone. The portable information terminal 9101 can display characters or an image on its plurality of surfaces. For example, three operation buttons 9050 (also referred to as operation icons, or simply icons) can be displayed on one surface of the display surface 9001. Furthermore, information 9051 indicated by dashed rectangles can be displayed on another surface of the display surface 9001. Note that examples of the information 9051 include display indicating reception of an e-mail, an SNS (social networking service), a telephone call, and the like, the title of an e-mail, an SNS, or the like, the sender of an e-mail, an SNS, or the like, date, time, remaining battery, and reception strength of an antenna. Alternatively, the operation buttons 9050 or the like may be displayed on the position where the information 9051 is displayed, in place of the information 9051.

The display device of one embodiment of the present invention can be used for the portable information terminal 9101. Consequently, the information terminal 9101 can display a high-quality image.

FIG. 13B is a perspective view illustrating a watch-type portable information terminal 9200. The portable information terminal 9200 is capable of executing a variety of applications such as mobile phone calls, e-mailing, reading and editing texts, music reproduction, Internet communication, and computer games. The display surface of the display surface 9001 is curved and provided, and display can be performed along the curved display surface. FIG. 13B illustrates an example in which time 9251, operation buttons 9252 (also referred to as operation icons or simply icons), and a content 9253 are displayed on the display surface 9001. The content 9253 can be a moving image, for example.

The portable information terminal 9200 can perform near field communication conformable to a communication standard. For example, mutual communication between the portable information terminal 9200 and a headset capable of wireless communication enables hands-free calling. The portable information terminal 9200 includes the connection terminal 9006, and data can be directly transmitted to and received from another information terminal via a connector. Power charging through the connection terminal 9006 is also possible. Note that the charging operation may be performed by wireless power feeding without through the connection terminal 9006.

The display device of one embodiment of the present invention can be used for the portable information terminal 9200. Consequently, the portable information terminal 9200 can display a high-quality image.

FIG. 13C, FIG. 13D, and FIG. 13E are perspective views illustrating a foldable portable information terminal 9201. FIG. 13C is a perspective view of the portable information terminal 9201 in the opened state, FIG. 13D is a perspective view of the portable information terminal 9201 that is shifted from one of the opened state and the folded state to the other, and FIG. 13E is a perspective view of the portable information terminal 9201 in the folded state. The portable information terminal 9201 is highly portable in the folded state and is highly browsable in the opened state because of a seamless large display region. The display surface 9001 of the portable information terminal 9201 is supported by three housings 9000 joined by hinges 9055. By being folded at the hinges 9055 between two housings 9000, the portable information terminal 9201 can be reversibly changed in shape from the opened state to the folded state. For example, the portable information terminal 9201 can be bent with a radius of curvature of greater than or equal to 1 mm and less than or equal to 150 mm.

The display device of one embodiment of the present invention can be used for the portable information terminal 9201. Consequently, the portable information terminal 9201 can display a high-quality image.

FIG. 13F is a perspective view illustrating a television device 9100. The television device 9100 can include the display surface 9001 having a large screen size of, for example, 50 inches or more, or 100 inches or more. The television device 9100 can be operated with a separate remote controller 9110 as well as the operation keys 9005. Alternatively, the display surface 9001 may include a touch sensor, and the television device 9100 may be operated by a touch on the display surface 9001 with a finger or the like. The remote controller 9110 may include a display surface for displaying data output from the remote controller 9110. With operation keys or a touch panel provided in the remote controller 9110, channels and volume can be controlled and videos displayed on the display surface 9001 can be controlled.

The display device of one embodiment of the present invention can be used for the television device 9100. Consequently, the television device 9100 can display a high-quality image.

At least part of this embodiment can be implemented in appropriate combination with the other embodiments or examples described in this specification.

### EXAMPLE 1

In this example, results of optical simulation (ray tracing) performed on the display device of one embodiment of the present invention will be described.

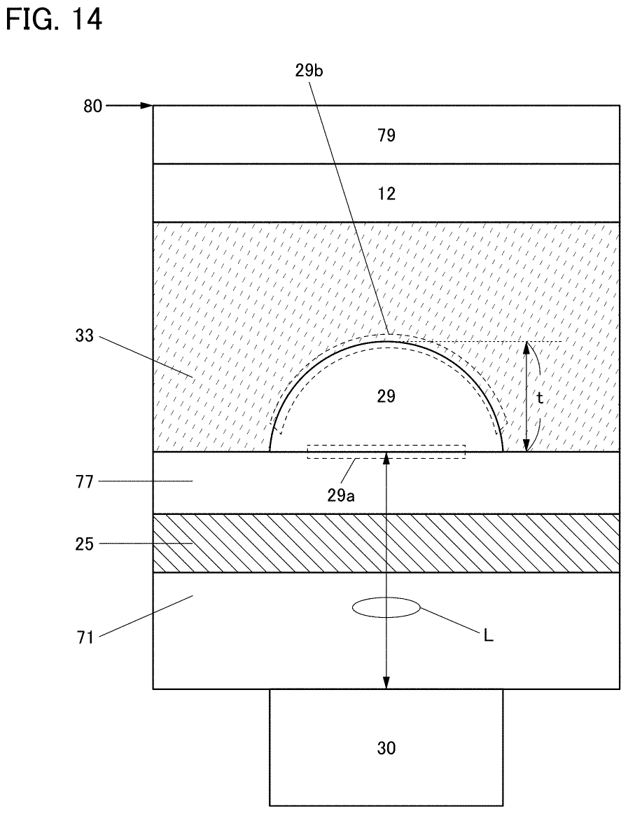

FIG. 14 is a schematic diagram of the display device used for the simulation in this example. As illustrated in FIG. 14, a layer 71 was provided over the light-emitting element 30, the coloring layer 25 was provided over the layer 71, and a layer 77 was provided over the coloring layer 25. In addition, the lens 29 was provided over the layer 77, the resin layer 33 was provided to cover the lens 29, the substrate 12 was provided over the resin layer 33, and a layer 79 was provided over the substrate 12.

The shape of the light-emitting element 30 when seen from the above was an ellipse with a long side of 1.9 μm and a short side of 1.6 μm.

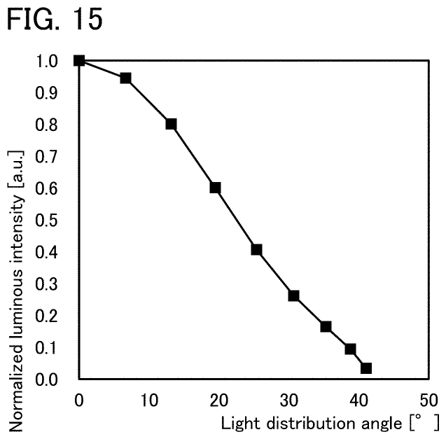

The light-emitting layer 31 included in the light-emitting element 30 had a structure in which a light-emitting layer emitting blue light and a light-emitting layer emitting yellow light were stacked. Light distribution characteristics of the light-emitting element 30 are as shown in FIG. 15. In FIG. 15, the normalized luminous intensity means the luminous intensity when the luminous intensity with a light distribution angle of 0° is 1. That is, FIG. 15 shows the light distribution characteristics of the light-emitting element 30 normalized with an angle of 0°.

The shape of the coloring layer 25 when seen from the above was a hexagon with a long side of 2.9 μm and a short side of 2.8 μm. The distance from a bottom surface of the coloring layer 25 to the flat portion 29a of the lens 29 was 2 μm.

The shape of the flat portion 29a of the lens 29 when seen from the above was an ellipse with a long side of 3.1 μm and a short side of 2.8 μm. The lens 29 was a semi-ellipsoid having the flat portion 29a as a bottom surface. Here, when seen from the above, the center of the light-emitting element 30, the center of the coloring layer 25, and the center of the lens 29 overlap with one another.

The refractive indices of the layer 71, the coloring layer 25, the layer 77, and the lens 29 were each 1.56. The refractive index of the resin layer 33 was 1.40. For the substrate 12, a glass substrate was used and the refractive index was 1.50. For the layer 79, air was used and the refractive index was 1.00. The thickness of the resin layer 33 was 3 μm, the thickness of the substrate 12 was 0.5 μm, and the thickness of the layer 79 was 400.5 μm. Here, an upper surface of the layer 79 was an evaluation plane 80.

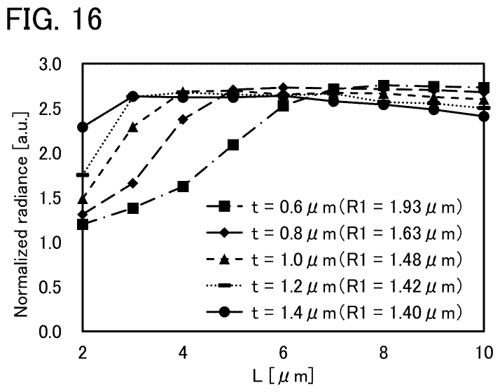

FIG. 16 is a graph showing simulation results of the relationship between the distance L and the normalized radiance of the light emitted by the light-emitting element 30 on the evaluation plane 80. Here, the thickness t of the lens 29 was 0.6 μm, 0.8 μm, 1.0 μm, 1.2 μm, or 1.4 μm. The radii R1 of curvature of cross sections along the short sides of the flat portions 29a with the respective thicknesses t were 1.93 μm, 1.63 μm, 1.48 μm, 1.42 μm, and 1.40 μm.

The diaphragm radius on the evaluation plane 80 was 10 μm. The radiance in the front of the light-emitting element 30 was found by simulation. In FIG. 16, the normalized radiance means the radiance on the evaluation plane 80 when the radiance is 1 without the lens 29. Specifically, the normalized radiance means the number of rays reaching the evaluation plane 80 under the respective conditions when the number of rays reaching the evaluation plane 80 is 1 without the lens 29.

FIG. 16 indicates that the normalized radiance is 1.0 or higher regardless of the distance L and the thickness t of the lens 29. In other words, according to FIG. 16, the lens 29 causes the light emitted by the light-emitting element 30 to be converged in the forward direction of the light-emitting element 30. Furthermore, according to FIG. 16, a larger thickness t (a smaller radius of curvature R1) indicates a higher radiance when the distance L is short, e.g., 6 μm or shorter; meanwhile, a smaller thickness t (a larger radius of curvature R1) indicates a higher radiance when the distance L is long, e.g., longer than 6 μm. For example, when the distance L is 4 μm, the radiance with a thickness t of 1.0 μm is the highest. By contrast, when the distance L is 7 μm, the radiance with a thickness t of 0.8 μm is the highest.

At least part of this embodiment can be implemented in appropriate combination with the other embodiments or examples described in this specification.

### EXAMPLE 2

In this example, the results of manufacture of the display device of one embodiment of the present invention and radiance measurements are described.

In this example, the display device illustrated in FIG. 1A was manufactured. Here, in the formation of the lens 29, a photosensitive film to be the lens 29 was applied. Next, light exposure and development were performed, and the film to be the lens 29 was processed into a desired shape. Then, the film to be the lens 29 was decolored by bleaching light exposure. After the decolorization, thermal reflow was performed at 105° C. for 10 minutes to make the film to be the lens 29 spherical. In this manner, the lens 29 was formed.

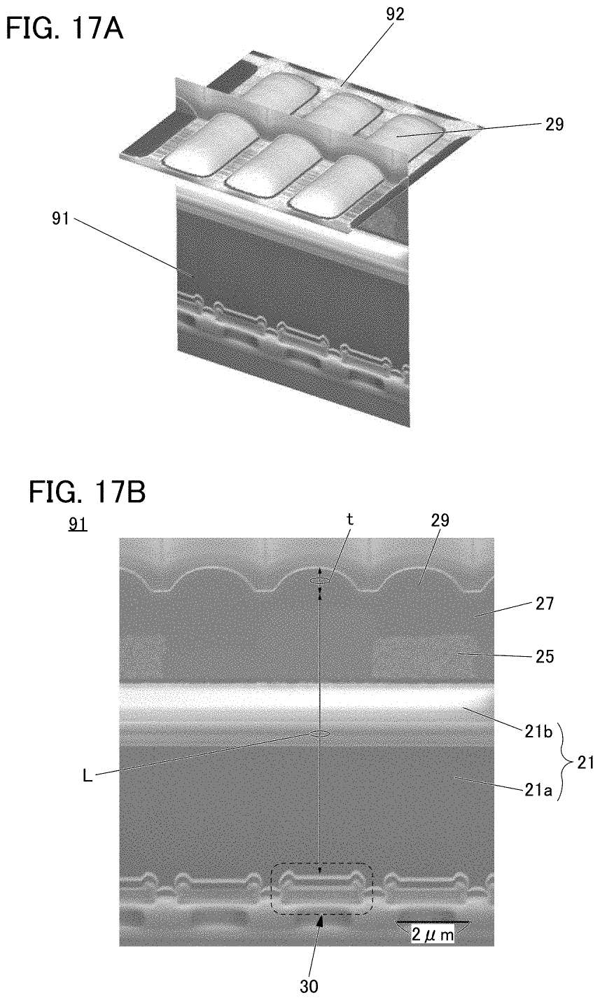

FIG. 17A and FIG. 17B show electron microscope images showing cross sections of the manufactured display device. FIG. 17A shows an image 91 and an image 92. The image 92 is an electron microscope image showing a cross section in the direction perpendicular to the image 91. The image 92 includes the lens 29. FIG. 17B shows the image 91.

As illustrated in FIG. 17A and FIG. 17B, the light-emitting element 30, the insulating layer 21, the coloring layer 25, the planarization layer 27, the lens 29, and the like having desired shapes can be formed; and it was confirmed that a pixel was able to be fabricated. The distance L from the light-emitting element 30 to the flat portion of the lens 29 was approximately 7 μm. Furthermore, the thickness t of the lens 29 was approximately 0.59 μm. Note that the insulating layer 21 was formed of a resin layer 21a and a protective layer 21b.

Next, the radiance of light emitted from the pixel 15 included in the manufactured display device was measured and compared with the optical simulation results.

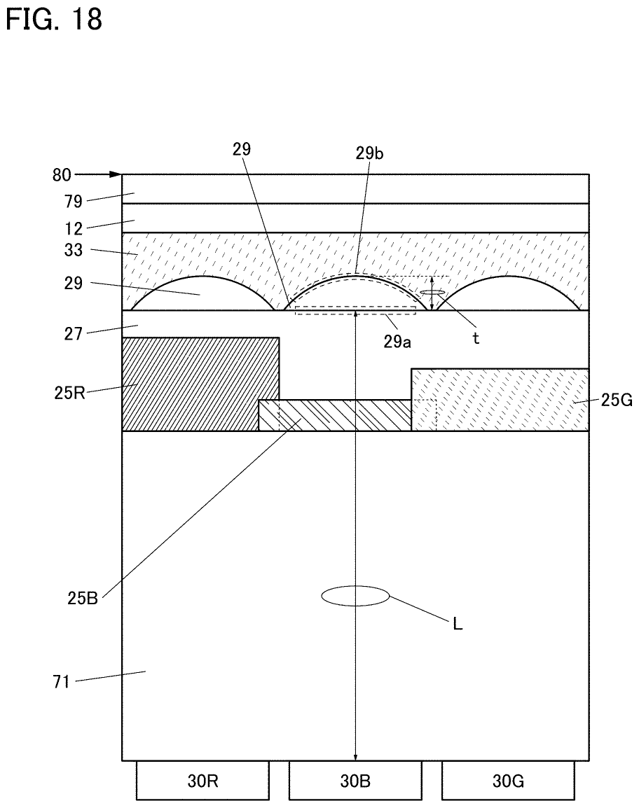

FIG. 18 is a schematic diagram of a display device used for the optical simulation in this example. As illustrated in FIG. 18, the layer 71 was provided over the light-emitting element 30, and the coloring layer 25R, the coloring layer 25B, and the coloring layer 25G were provided over the layer 71. The planarization layer 27 was provided over the coloring layer 25R, over the coloring layer 25B, and over the coloring layer 25G, and the lens 29 was provided over the planarization layer 27. Furthermore, the resin layer 33 was provided to cover the lens 29, the substrate 12 was provided over the resin layer 33, and the layer 79 was provided over the substrate 12. Here, the coloring layer 25R, the coloring layer 25B, and the coloring layer 25G included regions overlapping with the respective light-emitting elements 30 and lenses 29. In FIG. 18, the light-emitting element 30 overlapping with the coloring layer 25R is denoted by a light-emitting element 30R, the light-emitting element 30 overlapping with the coloring layer 25B is denoted by a light-emitting element 30B, and the light-emitting element 30 overlapping with the coloring layer 25G is denoted by a light-emitting element 30G.

Here, the distance L from the light-emitting layer 31 of the light-emitting element 30 to the flat portion 29a of the lens 29 was 7 μm on the basis of the actually measured value shown in FIG. 17.

The shape of the light-emitting element 30R when seen from the above was a rectangle with a long side of 7.15 μm and a short side of 1.95 μm. The shape of each of the light-emitting element 30B and the light-emitting element 30G when seen from the above was a rectangle with a long side of 7.10 μm and a short side of 1.48 μm. The light-emitting layer 31 included in the light-emitting element 30R, the light-emitting layer 31 included in the light-emitting element 30B, and the light-emitting layer 31 included in the light-emitting element 30G each had a structure in which a light-emitting layer emitting blue light and a light-emitting layer emitting yellow light were stacked.

The thickness of the coloring layer 25R was 1.8 μm and the width of the coloring layer 25R was 3.2 μm. The thickness of the coloring layer 25B was 0.72 uμm and the width of the coloring layer 25B was 2.9 μm. The thickness of the coloring layer 25G was 1.0 μm and the width of the coloring layer 25G was 2.9 μm. In addition, the refractive index of the coloring layer 25R was 1.768, the refractive index of the coloring layer 25B was 1.635, and the refractive index of the coloring layer 25G was 1.623.

The shape of the flat portion 29a of the lens 29 when seen from the above was a rectangle with a long side of 7.85 μm and a short side of 2.2 μm. The thickness t of the lens 29 was 0.59 μm on the basis of the actually measured value shown in FIG. 17. It was assumed that, when seen from the above, the center of the lens 29 was shifted from the center of the light-emitting element 30R, the center of the light-emitting element 30B, or the center of the light-emitting element 30G by 0.4 μm in the long side direction and by 0.2 μm in the short side direction.

The refractive index of the layer 71, the refractive index of planarization layer 27, and the refractive index of the lens 29 were each 1.56. The refractive index of the resin layer 33 was 1.40. For the substrate 12, a glass substrate was used and the refractive index was 1.50. For the layer 79, air was used and the refractive index was 1.00. Here, the upper surface of the layer 79 was the evaluation plane 80.

The optical simulation in this example was conducted to find the radiance of light emitted by the light-emitting element 30R, light emitted by the light-emitting element 30B, and light emitted by the light-emitting element 30G on the evaluation planes 80 in the front of the respective light-emitting elements. Here, the thickness of the layer 79 was 400.5 μm, and the upper surface of the layer 79 was the evaluation plane 80. The diaphragm radius on the evaluation plane 80 was 10 μm.

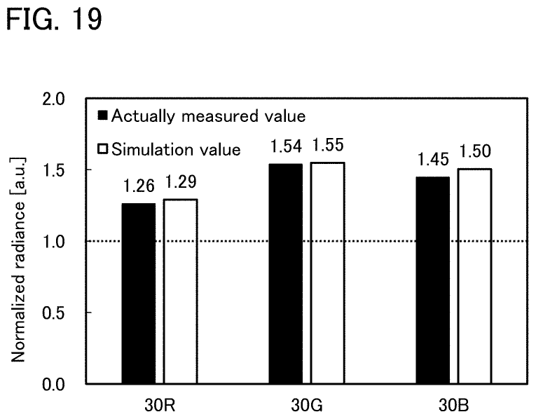

FIG. 19 is a graph showing the actual measurement results and the simulation results of the normalized radiance of the light emitted by the light-emitting element 30R, the light emitted by the light-emitting element 30G, and the light emitted by the light-emitting element 30B. The normalized radiance means the radiance on the evaluation plane 80 when the radiance is 1 without the lens 29. Specifically, the normalized radiance means the number of rays reaching the evaluation plane 80 under the respective conditions when the number of rays reaching the evaluation plane 80 is 1 without the lens 29.

As shown in FIG. 19, the actually measured value of the normalized radiance of the light-emitting element 30R is 1.26 and the simulation value by the optical simulation is 1.29. The actually measured value of the normalized radiance of the light-emitting element 30G is 1.54 and the simulation value by the optical simulation is 1.55. The actually measured value of the normalized radiance of the light-emitting element 30B is 1.45 and the simulation value by the optical simulation is 1.50.

It was thus confirmed that the normalized radiance of each of the light-emitting element 30R, the light-emitting element 30G, and the light-emitting element 30B was 1.0 or higher. In other words, it was confirmed that the light emitted by the light-emitting elements 30 was converged by the lens 29. Furthermore, the difference between the actually measured value and simulation value of the normalized radiance was 0.05 or less, which indicates that the optical simulation reproduced the actually measured value.

At least part of this embodiment can be implemented in appropriate combination with the other embodiments or examples described in this specification.

### REFERENCE NUMERALS

10: display device, 11: substrate, 12: substrate, 13: insulating layer, 14: partition, 15: pixel, 15B: pixel, 15G: pixel, 15R: pixel, 21: insulating layer, 21a: resin layer, 21b: protective layer, 25: coloring layer, 25B: coloring layer, 25G: coloring layer, 25R: coloring layer, 27: planarization layer, 29: lens, 29a: flat portion, 29b: convex portion, 30: light-emitting element, 30B: light-emitting element, 30G: light-emitting element, 30R: light-emitting element, 31: light-emitting layer, 33: resin layer, 35: partition, 37: adhesive layer, 42: conductive layer, 43: light, 45: light-blocking layer, 47: light, 49: light, 51: light-emitting layer, 52: transistor, 55G: wavelength-conversion layer, 55R: wavelength-conversion layer, 57: planarization layer, 60: conductive layer, 63: insulating layer, 71: layer, 77: layer, 79: layer, 80: evaluation plane, 91: image, 92: image, 152: insulating layer, 161: conductive layer, 162: insulating layer, 163: insulating layer, 164: insulating layer, 165: metal oxide layer, 166: conductive layer, 167: insulating layer, 168: conductive layer, 181: insulating layer, 182: insulating layer, 183: insulating layer, 184a: conductive layer, 184b: conductive layer, 185: insulating layer, 186: insulating layer, 187: insulating layer, 189a: conductive layer, 189b: conductive layer, 189c: conductive layer, 189d: conductive layer, 190: conductive layer, 195: conductive layer, 200: transistor, 205: conductor, 205a: conductor, 205b: conductor, 205c: conductor, 212: insulator, 214: insulator, 216: insulator, 222: insulator, 224: insulator, 230: oxide, 230a: oxide, 230b: oxide, 240: conductor, 240a: conductor, 240b: conductor, 241: insulator, 241a: insulator, 241b: insulator, 242: conductor, 242a: conductor, 242b: conductor, 243: oxide, 243a: oxide, 243b: oxide, 246: conductor, 246a: conductor, 246b: conductor, 250: insulator, 250a: insulator, 250b: insulator, 260: conductor, 260a: conductor, 260b: conductor, 271: insulator, 271a: insulator, 271b: insulator, 275: insulator, 280: insulator, 282: insulator, 283: insulator, 285: insulator, 8200: head-mounted display, 8201: wearing portion, 8202: lens, 8203: main body, 8204: display surface, 8205: cable, 8206: battery, 8300: head-mounted display, 8301: housing, 8302: display surface, 8304: wearing portion, 8305: lens, 8306: battery, 9000: housing, 9001: display surface, 9003: speaker, 9005: operation key, 9006: connection terminal, 9007: sensor, 9009: battery, 9050: operation button, 9051: information, 9055: hinge, 9100: television device, 9101: portable information terminal, 9110: remote controller, 9200: portable information terminal, 9201: portable information terminal, 9251: time, 9252: operation button, 9253: content

1. A display device comprising:
a first light-emitting element;
a first coloring layer;
a first lens;
a first substrate;
a second substrate;
an insulating layer;
a planarization layer; and
a resin layer,
wherein the first lens comprises a first flat portion and a first convex portion,
wherein the first light-emitting element is over the first substrate,
wherein the insulating layer is over the first light-emitting element,
wherein the first coloring layer is over the insulating layer, the first coloring layer comprising a region overlapping with the first light-emitting element,
wherein the planarization layer is over the first coloring layer,
wherein the first lens is provided, the first flat portion being in contact with the planarization layer and the first lens comprising a region overlapping with the first light-emitting element,
wherein the resin layer is in contact with the first convex portion,
wherein the second substrate is in contact with the resin layer, and
wherein a refractive index of the resin layer is lower than a refractive index of the first lens.

2. The display device according to claim 1, further comprising:
a second light-emitting element;
a second coloring layer; and
a second lens,
wherein the second lens comprises a second flat portion and a second convex portion,
wherein the second light-emitting element is over the first substrate,
wherein the insulating layer is over the second light-emitting element,
wherein the second coloring layer is over the insulating layer, the second coloring layer comprising a region overlapping with the second light-emitting element,
wherein the second lens is provided, the second flat portion being in contact with the planarization layer and the second lens comprising a region overlapping with the second light-emitting element,
wherein the resin layer is in contact with the second convex portion,
wherein the refractive index of the resin layer is lower than a refractive index of the second lens,
wherein the first coloring layer and the second coloring layer transmit light of colors that are different from each other, and
wherein a thickness of the first coloring layer is different from a thickness of the second coloring layer.

3. A display device comprising:
a light-emitting element;
a wavelength-conversion layer;
a lens;
a first substrate;
a second substrate;
an insulating layer;
a planarization layer; and
a resin layer,
wherein the lens comprises a flat portion and a convex portion,
wherein the light-emitting element is over the first substrate,
wherein the insulating layer is over the light-emitting element,
wherein the wavelength-conversion layer is over the insulating layer, the wavelength-conversion layer comprising a region overlapping with the light-emitting element,
wherein the planarization layer is over the wavelength-conversion layer,
wherein the lens is provided, the flat portion being in contact with the planarization layer and the lens comprising a region overlapping with the light-emitting element,
wherein the resin layer is in contact with the convex portion,
wherein the second substrate is in contact with the resin layer, and
wherein a refractive index of the resin layer is lower than a refractive index of the lens.

4. A display device comprising:
a first substrate;
a first light-emitting element;
a second light-emitting element;
an insulating layer;
a first coloring layer;
a second coloring layer;
a partition;
a first lens; and
a second lens,
wherein the first light-emitting element and the second light-emitting element are over the first substrate,
wherein the insulating layer is over the first light-emitting element and the second light-emitting element,
wherein the partition is over the insulating layer,
wherein the first coloring layer is over the insulating layer, the first coloring layer being in contact with a side surface of the partition and comprising a region overlapping with the first light-emitting element,
wherein the second coloring layer is over the insulating layer, the second coloring layer being in contact with a side surface of the partition and comprising a region overlapping with second light-emitting element,
wherein the first lens is over the first coloring layer, the first lens comprising a region overlapping with the first light-emitting element,
wherein the second lens is over the second coloring layer, the second lens comprising a region overlapping with the second light-emitting element, and
wherein a refractive index of the partition is lower than a refractive index of the first coloring layer and a refractive index of the second coloring layer.

5. The display device according to claim 4, further comprising a planarization layer,
wherein the first lens comprises a first flat portion and a first convex portion,
wherein the second lens comprises a second flat portion and a second convex portion,
wherein the planarization layer is over the first coloring layer and the second coloring layer, and
wherein the first flat portion and the second flat portion are in contact with the planarization layer.

6. The display device according to claim 4,
wherein a thickness of the first coloring layer is different from a thickness of the second coloring layer.

7. A display device comprising:
a first substrate;
a first light-emitting element;
a second light-emitting element;
an insulating layer;
a wavelength-conversion layer;
a partition;
a first lens; and
a second lens,
wherein the first light-emitting element and the second light-emitting element are over the first substrate,
wherein the insulating layer is over the first light-emitting element and the second light-emitting element,
wherein the partition is over the insulating layer,
wherein the wavelength-conversion layer is over the insulating layer, the wavelength-conversion layer being in contact with a side surface of the partition and comprising a region overlapping with the first light-emitting element,
wherein the first lens is over the wavelength-conversion layer, the first lens comprising a region overlapping with the first light-emitting element,
wherein the second lens is provided, the second lens comprising a region overlapping with the second light-emitting element, and
wherein a refractive index of the partition is lower than a refractive index of the wavelength-conversion layer.

8. The display device according to claim 7, further comprising a planarization layer,
wherein the first lens comprises a first flat portion and a first convex portion,
wherein the second lens comprises a second flat portion and a second convex portion,
wherein the planarization layer is over the wavelength-conversion layer, and
wherein the first flat portion and the second flat portion are in contact with the
planarization layer.

9. The display device according to claim 5, comprising:
a second substrate; and
a resin layer,
wherein the resin layer is in contact with the first convex portion and the second convex portion,
wherein the second substrate is in contact with the resin layer,
wherein a refractive index of the resin layer is lower than a refractive index of the first lens and a refractive index of the second lens.

10. The display device according to claim 2,
wherein the planarization layer is in contact with an upper surface and a side surface of the first coloring layer and with an upper surface and a side surface of the second coloring layer, and
wherein a refractive index of the planarization layer is lower than a refractive index of the first coloring layer and a refractive index of the second coloring layer.

11. The display device according to claim 10,
wherein the first lens is adjacent to the second lens, and
wherein the first coloring layer is apart from the second coloring layer.

12. The display device according to claim 1,
wherein the insulating layer is a planarized layer.

13. An electronic device comprising:
the display device according to claim 1; and
a battery.

14. A head-mounted display comprising:
the display device according to claim 1; and
a wearing portion.

15. The display device according to claim 8, comprising:
a second substrate; and
a resin layer,
wherein the resin layer is in contact with the first convex portion and the second convex portion,
wherein the second substrate is in contact with the resin layer,
wherein a refractive index of the resin layer is lower than a refractive index of the first lens and a refractive index of the second lens.

16. The display device according to claim 3,
wherein the insulating layer is a planarized layer.

17. An electronic device comprising:
the display device according to claim 3; and
a battery.

18. A head-mounted display comprising:
the display device according to claim 3; and
a wearing portion.

19. The display device according to claim 4,
wherein the insulating layer is a planarized layer.

20. The display device according to claim 7,
wherein the insulating layer is a planarized layer.
